(19) United States
(12) Patent Application Publication
(10) Pub. No.: US 2025/0389917 A1
(43) Pub. Date: Dec. 25, 2025

(54) PHOTONIC SEMICONDUCTOR PACKAGES AND METHOD OF FORMING THE SAME

(71) Applicant: Taiwan Semiconductor Manufacturing Co., Ltd., Hsinchu (TW)

(72) Inventors: Chia-Yen Tan, Taoyuan City (TW); Hung-Yi Kuo, Taipei City (TW); Yu-Min Liang, Zhongli City (TW); Hao-Yi Tsai, Hsinchu (TW)

(21) Appl. No.: 18/917,320

(22) Filed: Oct. 16, 2024

Related U.S. Application Data
(60) Provisional application No. 63/661,957, filed on Jun. 20, 2024.

(51) Int. Cl. G02B 6/43; G02B 6/42; H01L 23/29; H01L 25/16

(52) U.S. Cl. CPC G02B 6/43; G02B 6/4204; G02B 6/4239; G02B 6/428; H01L 23/293; H01L 25/167

(57) ABSTRACT

A method includes depositing a protective layer on a top surface of a photonic engine, wherein the top surface of the photonic engine includes a lens structure, wherein the protective layer covers the lens structure; depositing an encapsulant over the top surface of the photonic engine and the protective layer; and after depositing the encapsulant, removing the protective layer to expose the lens structure.

### PRIORITY CLAIM AND CROSS-REFERENCE

This application claims the benefit of U.S. Provisional Application No. 63/661,957, filed on Jun. 20, 2024, which application is hereby incorporated herein by reference.

### BACKGROUND

Optical signaling and processing are typically combined with electrical signaling and processing to provide full-fledged applications. For example, optical fibers may be used for long-range signal transmission, and electrical signals may be used for short-range signal transmission as well as processing and controlling. Accordingly, devices integrating long-range optical components and short-range electrical components are formed for the conversion between optical signals and electrical signals, as well as the processing of optical signals and electrical signals. Packages thus may include both optical (photonic) components and electronic devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, 5, 6, 7, and 8 illustrate intermediate steps in the formation of an optical engine, in accordance with some embodiments.

FIGS. 9, 10, 11, 12, 13, 14, and 15 illustrate various views of intermediate steps in the formation of a package component, in accordance with some embodiments.

FIGS. 16, 17, 18, 19, and 20 illustrate cross-sectional views of intermediate steps in the formation of a package, in accordance with some embodiments.

FIGS. 21, 22, 23, and 24 illustrate cross-sectional views of intermediate steps in the formation of a package, in accordance with some embodiments.

FIG. 25 illustrates a cross-sectional view of a package, in accordance with some embodiments.

FIGS. 26, 27, 28, and 29 illustrate intermediate steps in the formation of an optical engine, in accordance with some embodiments.

FIGS. 30, 31, 32, 33, and 34 illustrate various views of intermediate steps in the formation of a package component, in accordance with some embodiments.

FIGS. 35, 36, 37, and 38 illustrate cross-sectional views of intermediate steps in the formation of a package, in accordance with some embodiments.

FIG. 39 illustrates a cross-sectional view of a package, in accordance with some embodiments.

FIGS. 40, 41, 42, and 43 illustrate cross-sectional views of intermediate steps in the formation of a package, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various structures such as packages comprising photonic structures, optical engines, or the like and their methods of formation are described herein. During formation of a package, a lens of an optical engine is temporarily covered by a protective coating. The protective coating protects the lens from damage during manufacture of the package. The protective coating can be removed using a selective etch. After removing the protective coating, a fiber coupling may be attached to the package to optically couple the lens. In some cases, the use of protective coating may form an opening over the optical engine that allows for improved attachment of the fiber coupling.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

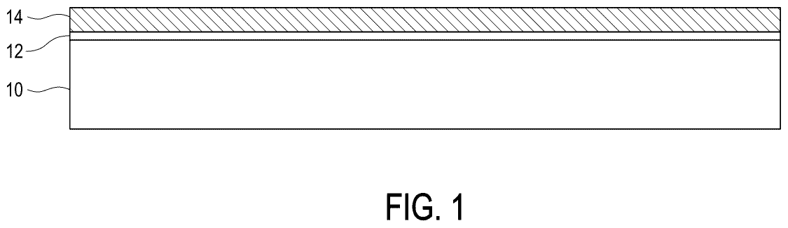

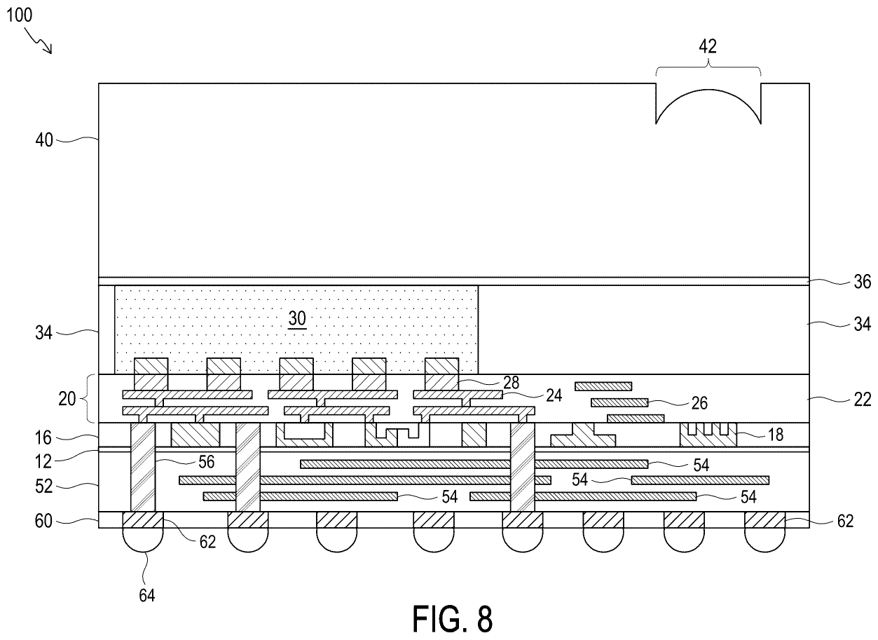

FIGS. 1 through 8 illustrate intermediate steps in the formation of an optical engine 100 (see FIG. 8), in accordance with some embodiments. The optical engine 100 comprises waveguides, photonic components, and integrated circuits that may be configured to receive, generate, modify, transmit, and/or process optical signals. In some embodiments, the optical engine 100 provides an input/output (I/O) interface between optical signals and electrical signals in a package or package component. In some embodiments, the optical engine 100 provides an optical network for signal communication between various components (e.g., photonic devices, integrated circuits, couplings to external fibers, etc.). In this manner, the optical engine 100 can enable optical-electrical (OE) conversion for package-level optical communication (e.g., within a package). In some cases, the optical engine 100 may be considered a photonic package component, an optical package module, a silicon photonic device, or the like.

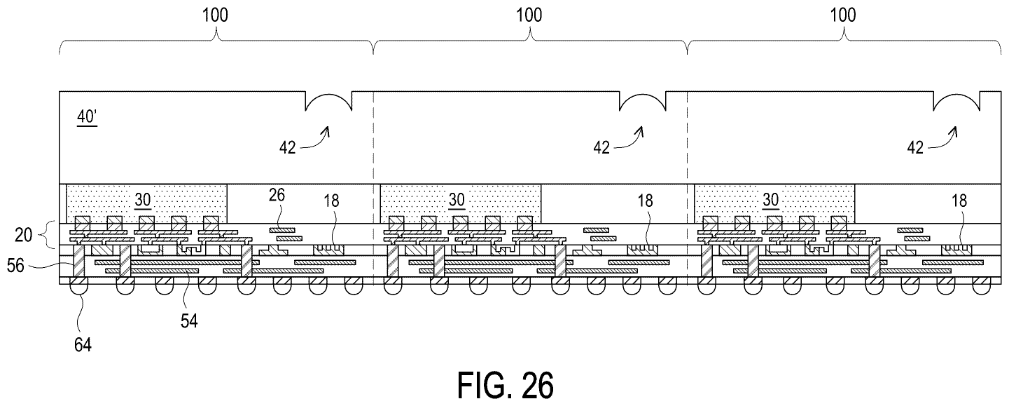

Turning to FIG. 1, the optical engine 100 comprises at this stage a substrate 10, a dielectric layer 12, and photonic layer 14, in accordance with some embodiments. In an embodiment, at a beginning of the manufacturing process of the optical engine 100, the substrate 10, the dielectric layer 12, and the photonic layer 14 may collectively be part of a silicon-on-insulator (SOI) substrate or the like, which may be doped (e.g., with a p-type or an n-type dopant) or undoped. In some embodiments, the substrate 10 may be a wafer, such as a silicon wafer. Other substrates, such as a silicon-on-insulator (SOI) substrate, a multi-layered substrate, or a gradient substrate may also be used. In some embodiments, the semiconductor material of the substrate 10 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. In other embodiments, the substrate 10 may be a dielectric material such as silicon oxide, glass, ceramic, plastic, or any other suitable material that allows for structural support of overlying devices. Other substrates, such as a multi-layered or gradient substrate, may also be used. The substrate 10 may be free of passive or active devices, in some cases. In some embodiments, multiple optical engine 100 are formed on a single substrate 10 and then are subsequently singulated into individual optical engine 100. An example embodiment in which multiple optical engines 100 are formed on the same substrate 10 is described below for FIGS. 26-29, and the optical engine 100 of FIGS. 1-8 may be formed similarly in some embodiments.

The dielectric layer 12 may be a dielectric layer that separates the substrate 10 from the overlying photonic layer 14. In some embodiments, the dielectric layer can also serve as a portion of cladding material that surrounds the subsequently manufactured photonic components 18 (described below). In an embodiment, the dielectric layer 12 may be silicon oxide, silicon nitride, germanium oxide, germanium nitride, the like, or a combination thereof. The dielectric layer 12 may be formed using a technique such as implantation (e.g., to form a buried oxide (BOX) layer) or using a suitable deposition technique such as chemical vapor deposition (CVD), atomic layer deposition (ALD), physical vapor deposition (PVD), combinations of these, or the like. However, any suitable material and method of manufacture may be used.

The photonic layer 14 is formed over the dielectric layer 12. In some embodiments, the photonic layer 14 may be a semiconductor material such as silicon, germanium, silicon germanium, the like, or a combination thereof. In other embodiments, the photonic layer 14 may comprise a dielectric material such as silicon nitride or the like, a III-V semiconductor material, a compound semiconductor material, lithium niobate materials, polymers, the like, or a combination thereof. The photonic layer 14 may be formed using a suitable technique, such as epitaxial growth, CVD, ALD, PVD, the like, or combinations thereof. Other materials or techniques are possible. In some cases, the photonic layer 14 may be considered an “active layer” or the like.

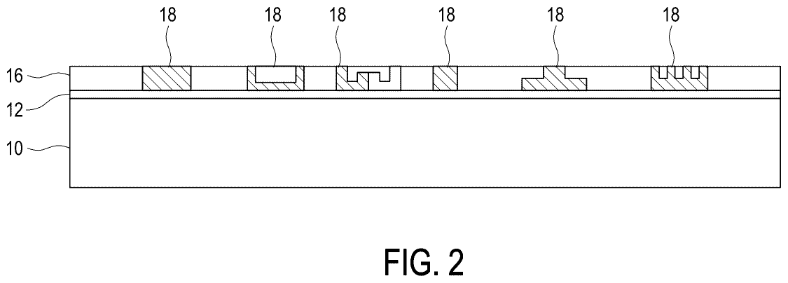

FIG. 2 illustrates the formation of photonic components 18 from the photonic layer 14, in accordance with some embodiments. In some embodiments, the photonic components 18 may include such devices or components as optical waveguides (e.g., ridge waveguides, rib waveguides, buried channel waveguides, diffused waveguides, etc.), couplers (e.g., grating couplers, edge couplers, such as edge couplers comprising a tip waveguide having a width in the range of about 1 nm to about 200 nm, etc.), directional couplers, optical modulators (e.g., germanium modulators, Mach-Zehnder silicon-photonic switches, microelectromechanical switches, micro-ring resonators, etc.), amplifiers, multiplexors, demultiplexors, optical-to-electrical converters (e.g., photodetectors, P-N junctions, or the like), electrical-to-optical converters, lasers (e.g., laser diodes), phase shifters, combinations of these, or the like. However, the photonic components 18 may comprise other devices, structures, or components than these examples.

In some embodiments, the photonic components 18 may be formed by patterning the photonic layer 14 into the appropriate shapes for the photonic components 18. For example, photonic layer 14 may be patterned using one or more photolithographic masking and etching processes, though any suitable methods of patterning the photonic layer 14 may be utilized. The patterning may expose portions of the dielectric layer 12. In some cases, additional processing steps may be performed to form some types of photonic components 18, such as additional implantation processes, deposition processes, epitaxial growth processes, and/or patterning processes. In some embodiments, one or more photonic components 18 may be formed by patterning the photonic layer 14 and then depositing another material on portions of the patterned photonic layer 14. For example, the formation of a photonic components 18 may comprise patterning a photonic layer 14 comprising silicon and then epitaxially growing a region of germanium on the patterned photonic layer 14. Other materials, techniques, or process steps are possible.

Sill referring to FIG. 2, a dielectric layer 16 may be formed over the dielectric layer 12 and/or the photonic components 18, in accordance with some embodiments. The dielectric layer 16 may be, for example, a dielectric material that separates the individual photonic components 18 from each other and from the overlying structures. Further, in some cases, the dielectric layer 16 can serve as a cladding material that at least partially surrounds one or more photonic components 18. In some embodiments, the dielectric layer 16 may comprise silicon oxide, silicon nitride, germanium oxide, germanium nitride, combinations of these, or the like, which may be formed using suitable deposition techniques such as CVD, ALD, PVD, or the like. Other materials or deposition techniques are possible. In some embodiments, after depositing the dielectric layer 16, a planarization process (e.g., a chemical mechanical polishing (CMP) process, a grinding process, or the like) may be performed to planarize a top surface of the dielectric layer 16. In some embodiments, the planarization process may expose a top surface of one or more photonic components 18. In such embodiments, top surfaces of some photonic components 18 and top surfaces of the dielectric layer 16 may be level or coplanar (within process variations). In some embodiments, one or more photonic components 18 remain covered by the dielectric layer 16 after performing the planarization process.

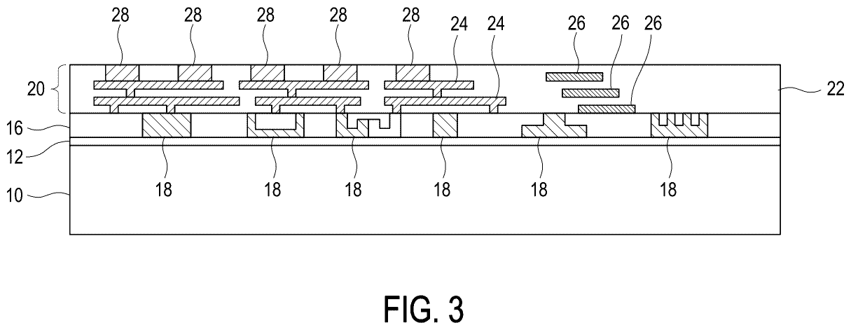

FIG. 3 illustrates the formation of an interconnect structure 20 over the photonic components 18, in accordance with some embodiments. The interconnect structure 20 includes dielectric layers 22 (not individually illustrated) with conductive features 24 formed in the dielectric layers 22, in some embodiments. The conductive features 24 allow for electrical communication within the optical engine 100. The conductive features 24 may comprise conductive lines, conductive vias, conductive pads, metallization patterns, redistribution layers, or the like that provide electrical interconnections and electrical routing within the optical engine 100. Some conductive features 24 may be electrically connected to one or more photonic components 18, in some cases. The interconnect structure 20 may also comprise conductive pads 28 at a top surface of the interconnect structure 20, in some embodiments. The conductive pads 28 may be metal pads, bonding pads, or the like.

In some embodiments, the interconnect structure 20 is formed of alternating layers of dielectric material (e.g., dielectric layers 22) and conductive material (e.g., conductive features 24). The conductive features 24 may be formed using any suitable processes such as deposition, damascene, dual damascene, or the like. In particular embodiments, the interconnect structure 20 may have multiple layers of conductive features 24, but the precise number of layers of conductive features 24 may be dependent upon the design of the optical engine 100. The dielectric layers 22 may be, for example, insulating layers and/or passivating layers, and may comprise silicon oxide, silicon nitride, a polymer, a molding material, the like, or a combination thereof. The conductive features 24 may include, for example, a metal or a metal alloy such as copper, silver, gold, tungsten, cobalt, ruthenium, aluminum, alloys thereof, combinations thereof, or the like. Other materials or formation techniques are possible.

In some embodiments, the conductive pads 28 are formed in the topmost dielectric layer 22 (not separately illustrated) of the dielectric layers 22. In some embodiments, the conductive pads 28 may include via portions (not separately illustrated) that physically and electrically contact underlying conductive features 24. In some embodiments, the topmost dielectric layer 22 of the interconnect structure 20 may be a material suitable for dielectric-to-dielectric bonding, such as silicon oxide, silicon nitride, silicon oxynitride, or the like. Other materials are possible. In some embodiments, the conductive pads 28 may be formed by first forming openings (not separately illustrated) in the topmost dielectric layer 22 that expose conductive portions of some underlying conductive features 24, depositing an optional liner in the openings, and then depositing a conductive material in the openings. The conductive material may be similar to those described for the conductive features 24. For example, the conductive material may be copper or a copper alloy, in some embodiments. A planarization process (e.g., a CMP process or a grinding process) may be performed to remove excess conductive material such that top surfaces of the conductive pads 28 and the topmost dielectric layer 22 are approximately level. This is an example, and the conductive pads 28 may be formed using other materials, techniques, or process steps.

Additionally, during the manufacture of the interconnect structure 20, one or more photonic components 26 may be formed within the dielectric layers 22, in accordance with some embodiments. The photonic components 26 may be similar to the photonic components 18 described previously. For example, in some embodiments, the photonic components 26 may include waveguides (e.g., silicon nitride waveguides), couplers, or the like. In some cases, one or more photonic components 26 may be optically coupled to each other and/or to one or more photonic components 18. In this manner, the photonic components 18 and the photonic components 26 may provide optical communication and optical interconnection within the optical engine 100.

In some embodiments, photonic components 26 may be formed during the manufacture of the interconnect structure 20 by depositing a material for photonic components 26 on a dielectric layer 22. The material for the photonic components 26 may be a dielectric material such as silicon nitride, silicon oxide, silicon oxynitride, polymer, combinations of these, or the like, or a semiconductor material such as silicon, germanium, or the like. The material may then be patterned into suitable shapes for the photonic components 26 using suitable photolithography and etching techniques. Another dielectric layer 22 may then be deposited on the photonic components 26. In particular embodiments, the interconnect structure 20 may have multiple layers of photonic components 26, but the precise number of layers of photonic components 26 may be dependent upon the design of the optical engine 100.

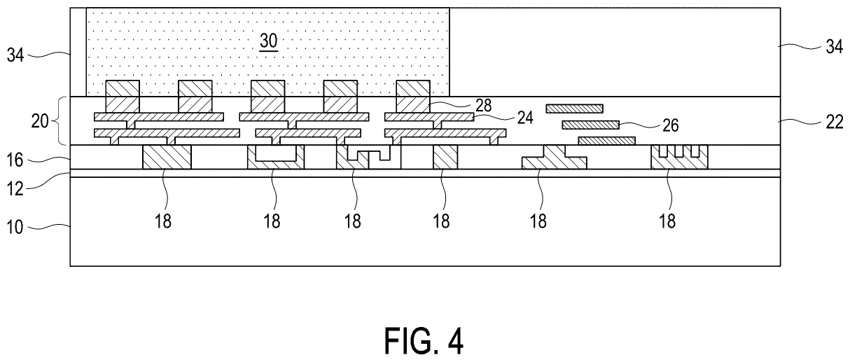

In FIG. 4, an electronic die 30 is bonded to the interconnect structure 20, in accordance with some embodiments. The electronic die 30 may be, for example, a semiconductor device, die, or chip that may comprise integrated circuits and may interact with the photonic components 106 using electrical signals. For example, the electronic die 30 may include controllers, drivers, transimpedance amplifiers, transistors, other active devices, resistors, capacitors, other passive devices, the like, or combinations thereof. Accordingly, the electronic die 30 may be considered an electronic integrated circuit (EIC) structure or the like. In some embodiments, the integrated circuits may be configured to interface with the photonic components 18. For example, the electronic die 30 may process electrical signals received from photonic components 18, may control the operation of the photonic components 18, and/or may generate electrical signals that photonic components 18 convert into optical signals. One electronic die 30 is shown in FIG. 4, but an optical engine 100 may include two or more electronic dies 30 in other embodiments.

In some embodiments, the electronic die 30 may provide Serializer/Deserializer (SerDes) functionality. In this manner, the electronic die 30 may act as part of an I/O interface between optical signals and electrical signals within the optical engine 100 or within a package or package component comprising the optical engine 100. In some embodiments, an electronic die 30 may comprise one or more processing devices, such as a Central Processing Unit (CPU or “xPU”), a Graphics Processing Unit (GPU), an Application-Specific Integrated Circuit (ASIC), a High-Performance Computing (HPC) die, a logic die, the like, or a combination thereof. An electronic die 30 may include one or more memory devices, which may be a volatile memory such as Dynamic Random-Access Memory (DRAM), Static Random-Access Memory (SRAM), High-Bandwidth Memory (HBM), another type of memory, or the like. Other electronic dies 30 or configurations thereof are possible.

In some embodiments, the electronic die 30 may include bond pads formed in a bonding layer, and the electronic die 30 is bonded to the interconnect structure 20 by dielectric-to-dielectric bonding and/or metal-to-metal bonding (e.g., direct bonding, fusion bonding, oxide-to-oxide bonding, hybrid bonding, or the like). In some embodiments, a bonding layer (e.g., an exposed dielectric layer) of the electronic die 30 is bonded to a bonding layer (e.g., an exposed dielectric layer, such as the top-most dielectric layer) of the interconnect structure 20 using a dielectric-to-dielectric bonding process, and conductive pads of the electronic die 30 are bonded to corresponding conductive pads 28 of the interconnect structure 20 using a metal-to-metal bonding process. In some embodiments, the bonding process may be initiated by activating the bonding surfaces of the electronic die 30 and the interconnect structure 20, which can facilitate bonding of the bonding surfaces. Activating the bonding surfaces may comprise, for example, a dry treatment, a wet treatment, a plasma treatment, exposure to an inert gas plasma, exposure to H₂, exposure to N₂, exposure to O₂, combinations thereof, or the like. For embodiments in which a wet treatment is used, an RCA cleaning process may be used, for example. In other embodiments, the activation process may comprise other types of treatments. After the activation process, the electronic die 30 is aligned and placed into physical contact with the interconnect structure 20. The electronic die 30 and the interconnect structure 20 are then subjected to a thermal treatment and contact pressure to bond respective bonding layers together with dielectric-to-dielectric bonding and bond the conductive pads of the electronic die 30 to the conductive pads 28 of the interconnect structure 20 with metal-to-metal bonding. In some embodiments, the resulting bonded structure is subsequently baked, annealed, pressed, or otherwise treated to strengthen or finalize the bond. This is an example, and other bonding processes are possible. In other embodiments, the electronic dies 30 may comprise conductive connectors (e.g. solder bumps or the like), and may be bonded to the interconnect structure 20 using these conductive connectors.

Further in FIG. 4, a dielectric material 34 is formed over the electronic die 30 and the interconnect structure 20, in accordance with some embodiments. The dielectric material 34 may be formed of silicon oxide, silicon nitride, a polymer, the like, or a combination thereof. The dielectric material 34 may be formed by CVD, PVD, ALD, a spin-on process, the like, or a combination thereof. In some embodiments, the dielectric material 34 may be formed by HDP-CVD, FCVD, PECVD, the like, or a combination thereof. The dielectric material 34 may be a gap-fill material in some embodiments, which may include one or more of the example materials above. In some embodiments, the dielectric material 34 may be a material (e.g., silicon oxide) that is substantially transparent to light at wavelengths suitable for transmitting optical signals or optical power. For example, the dielectric material 34 may allow optical signals or optical power to be transmitted between a photonic component 18 (e.g., a grating coupler or the like) and an overlying optical fiber coupler or the like. The dielectric material 34 may be a material similar to that of the dielectric layers 22 and/or the dielectric layer 16, in some embodiments. Other dielectric materials formed by any acceptable processes may be used. The dielectric material 34 may be planarized using a planarization process such as a CMP process, a grinding process, or the like. In some embodiments, the planarization process may expose the electronic die 30 such that surfaces of the electronic die 30 and the dielectric material 34 are coplanar.

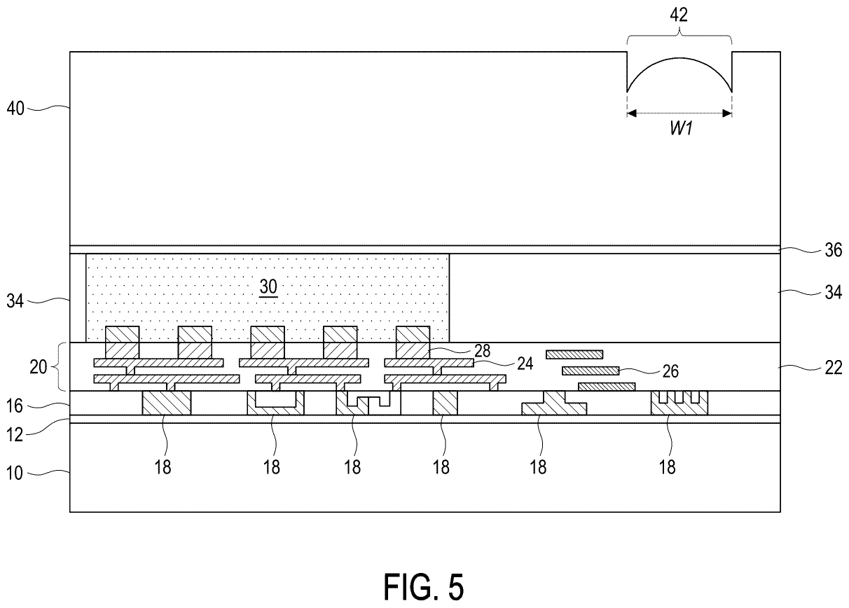

In FIG. 5, a support 40 is attached to the structure, in accordance with some embodiments. The support 40 is a rigid structure that is attached to the structure in order to provide structural or mechanical stability. The use of a support 40 can reduce warping or bending, which can improve the performance of the photonic components 18 within the optical engine 100. The support 40 may be attached to the structure (e.g., to the dielectric material 34 and/or the electronic die 30) using a bonding layer 36 formed over the dielectric material 34 and the electronic die 30, in accordance with some embodiments. The bonding layer 36 may be an adhesive layer, in some embodiments. In other embodiments, the bonding layer 36 may be a dielectric layer suitable for dielectric-to-dielectric bonding of the support 40. For example, the bonding layer 36 may be deposited on the dielectric material 34 and the electronic die 30, and then the support 40 may be bonded to the bonding layer 36 using suitable dielectric-to-dielectric bonding techniques.

In some embodiments, the support 40 is formed of materials transparent to relevant wavelengths of light such that optical signals may be transmitted through the support 40. In some embodiments, a lens 42 is formed in the upper surface of the support 40. The lens 42 may be optically coupled to a photonic component 18 through the support 40. In some embodiments, the lens 42 facilitates optical coupling between a photonic component 18 (e.g., a grating coupler or the like) and an overlying optical fiber coupler or the like. In some embodiments, the lens 42 is formed in the support 40 using one or more patterning steps, which may include suitable photolithography and etching processes. In this manner, the lens 42 may comprise a recess or the like in the top surface of the support 40. In other embodiments, the lens 42 is formed separately and is attached to the support 40. In some embodiments, an index-matching material or the like (not shown) is deposited over the lens 42. In some embodiments, a support 40 may include multiple lenses 42. The lens 42 shown in FIG. 5 is an example, and lenses 42 may be lens structures having other shapes or sizes than shown.

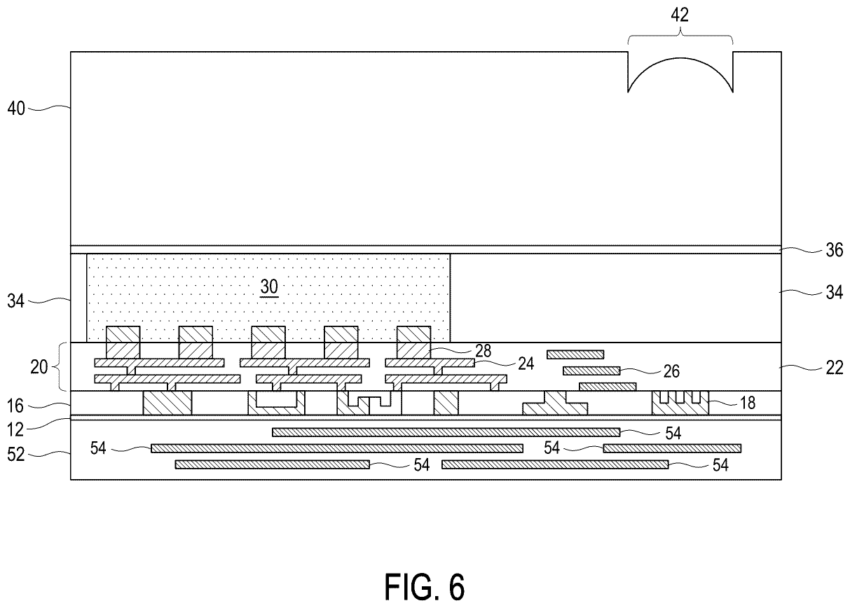

In FIG. 6, the substrate 10 is removed and waveguides 54 are formed, in accordance with some embodiments. The substrate 10 may be removed using a planarization process (e.g., a CMP process, a grinding process, or the like) and/or an etching process. In some embodiments, removing the substrate 10 exposes the dielectric layer 12. Removing the substrate 10 may include thinning the dielectric layer 12, in some embodiments. In some embodiments, the dielectric layer 12 is used as a stop layer during removal of the substrate 10. In other embodiments, the dielectric layer 12 is removed.

After removing the substrate 10, waveguides 54 are then formed over the dielectric layer 12, in accordance with some embodiments. The waveguides 54 may allow for optical communication within the optical engine 100, and some waveguides 54 may be optically coupled to photonic components 18. For example, one or more waveguides 54 may receive optical signals from photonic components 18 and/or transmit optical signals to photonic components 18. In some embodiments, one or more layers of waveguides 54 may be formed within multiple dielectric layers 52 (not individually illustrated). FIG. 6 illustrates three layers of waveguides 54, but more or fewer waveguides 54 or layers of waveguides 54 may be present. In some embodiments, a waveguide 54 may be optically coupled to an adjacent waveguide 54, to an overlying waveguide 54 of another layer, and/or to an underlying waveguide 54 of another layer. One or more waveguides 54 may be optically coupled to photonic components 18, in some embodiments. For example, a photonic component 18 (e.g., a waveguide or the like) may be optically coupled to an underlying waveguide 54. Waveguides 54 may be optically coupled using suitable techniques, such as using evanescent coupling, grating couplers, or other optical coupling techniques.

In some embodiments, a layer of waveguides 54 may be formed by depositing a waveguide material on a dielectric layer 52 and then patterning the waveguide material. In some embodiments, the waveguide material may be deposited on the dielectric layer 12 and thus the resulting waveguides 54 are formed on the dielectric layer 12. In other cases, the waveguide material is deposited on a previously deposited dielectric layer 52. The waveguide material may be a dielectric material such as silicon nitride, silicon oxide, silicon oxynitride, polymer, combinations of these, or the like. In other embodiments, the waveguide material may be a semiconductor material such as silicon, germanium, or the like. The waveguide material may be deposited using a suitable technique, such as ALD, PVD, or the like. The waveguide material may then be patterned using suitable photolithography and etching techniques to form a layer of waveguides 54. A dielectric layer 52 may then be deposited over a layer of the waveguides 54. The dielectric layers 52 may be a material similar to the dielectric layer 16 or the dielectric layer 22, such as silicon oxide or the like. The steps of depositing a waveguide material, patterning the waveguide material to form a layer of waveguides 54, and then depositing a dielectric layer 52 over the layer of waveguides 54 may be repeated to form multiple layers of waveguides 54.

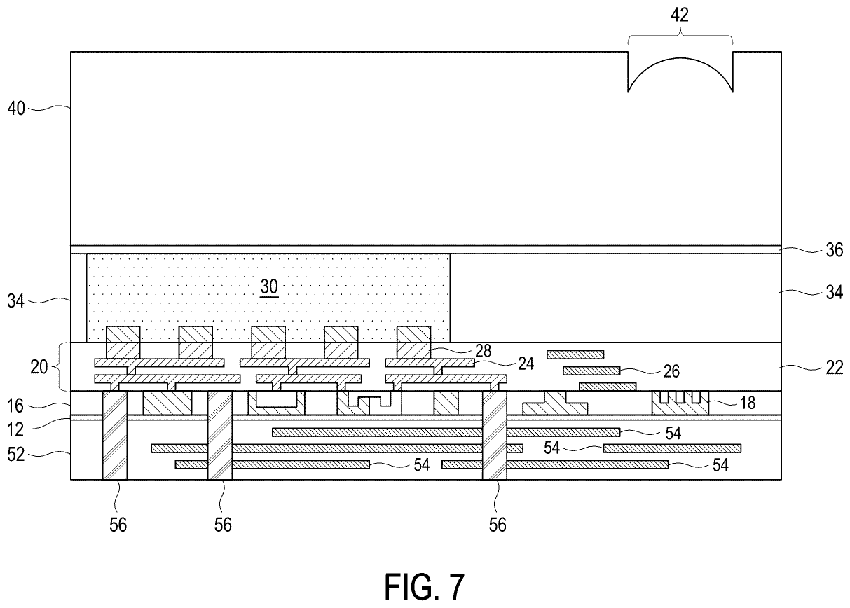

In FIG. 7, vias 56 are formed extending through the dielectric layer(s) 52, the dielectric layer 12, and the dielectric layer 16, in accordance with some embodiments. The vias 56 may physically and electrically contact conductive features 24 of the interconnect structure 20. In some embodiments, the vias 56 may extend into one or more of the dielectric layers 22 of the interconnect structure 20. The vias 56 may be formed, for example, by forming openings extending through the dielectric layer(s) 52, the dielectric layer 12, and the dielectric layer 16, and/or one or more dielectric layers 22 to expose surfaces of the conductive features 24. The openings may be formed using acceptable photolithography and etching techniques, such as by forming and patterning a photoresist and then performing an etching process using the patterned photoresist as an etching mask. The etching process may include, for example, a dry etching process and/or a wet etching process. A conductive material may then be deposited in the openings, thereby forming the vias 56. In some embodiments, a liner (not shown) may be deposited in the openings prior to forming the conductive material. The conductive material may comprise, for example, a metal or a metal alloy such as copper, silver, gold, tungsten, cobalt, aluminum, alloys thereof, or the like. A planarization process (e.g., a CMP process or a grinding process) may be performed to remove excess conductive, such that surfaces of the vias 56 and a dielectric layer 52 are level. Other materials or techniques are possible. In other embodiments, the vias 56 are formed at another stage of the manufacturing process than the embodiment shown.

In FIG. 8, conductive connectors 64 are formed, in accordance with some embodiments. The conductive connectors 64 may be used to electrically connect the optical engine 100 to an external structure such as a package substrate, an organic core substrate, an interposer, or the like. In some embodiments, an optional passivation layer 60 is formed over a dielectric layer 52. The passivation layer 60 may comprise, for example, a polymer such as polybenzoxazole (PBO), polyimide, a benzocyclobuten (BCB) based polymer, or the like; a nitride such as silicon nitride or the like; an oxide such as silicon oxide, PSG, BSG, BPSG, or the like; an encapsulant, molding compound, or the like; the like, or a combination thereof. The passivation layer 60 may be formed, for example, by spin coating, lamination, CVD, PVD, ALD, or the like.

Under-bump metallizations (UBMs) 62 may then be formed within the passivation layer 60 to make physical and electrical contact to the vias 56. In other embodiments, the UBMs 62 are formed prior to forming the passivation layer 60. In some embodiments, the UBMs 62 have bump portions on and extending along the major surface of the passivation layer 60. The UBMs 62 may be formed of one or more conductive materials using a suitable process, such as plating. In some embodiments, the UBMs 62 are not formed.

The conductive connectors 64 are then formed on the UBMs 62, in accordance with some embodiments. The conductive connectors 64 may be, for example, ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 64 may include a conductive material such as solder, copper, aluminum, gold, nickel, silver, palladium, tin, the like, or a combination thereof. In some embodiments, the conductive connectors 64 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 64 comprise metal pillars (such as a copper pillar) formed by a sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process. In other embodiments, the conductive connectors 64 are omitted and the UBMs 62 are bonding pads used for metal-to-metal bonding to an external component. In this manner, an optical engine 100 may be formed. The optical engine 100 shown in FIG. 8 is an example, and other process steps, materials, configurations, or arrangements are possible

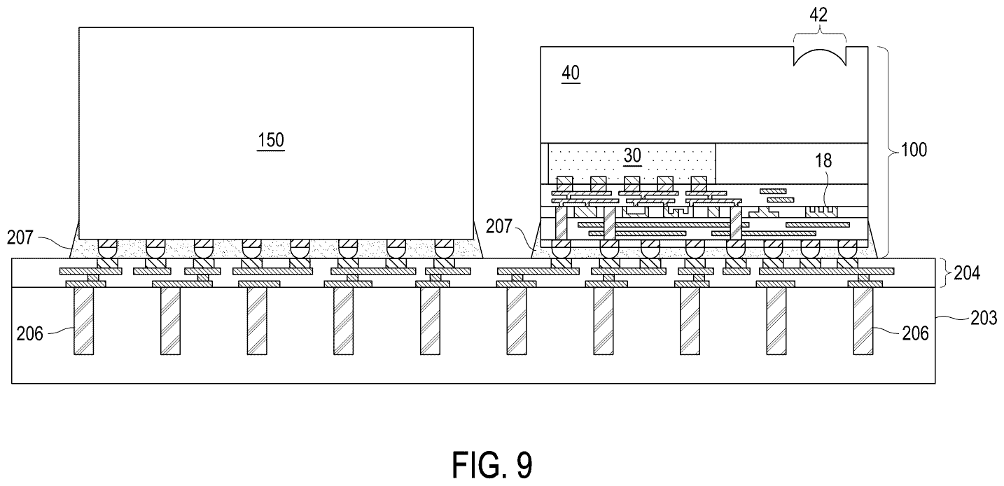

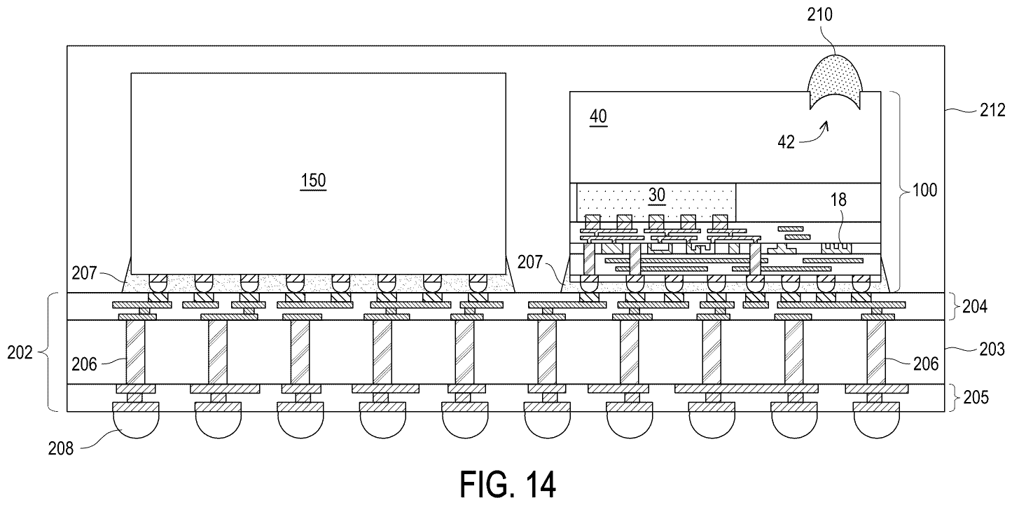

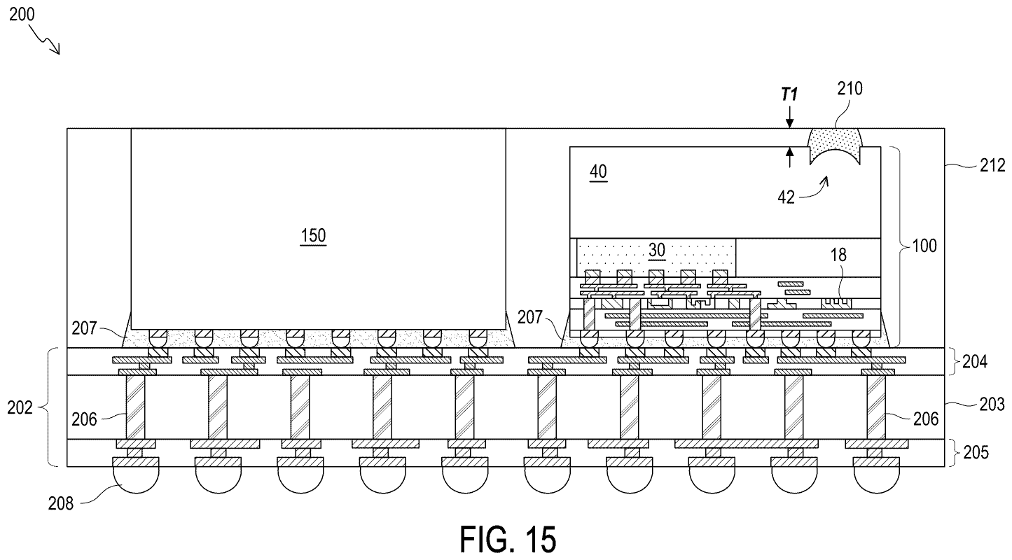

FIGS. 9 through 15 illustrate intermediate stages in the manufacturing of a package component 200 (see FIG. 15), in accordance with some embodiments. The package component 200 may include one or more optical engines 100 and one or more semiconductor dies 150 attached to an interposer structure 202 (see FIG. 14). In some cases, the package component 200 may be considered a chip-on-wafer (CoW) structure or the like. In FIG. 9, an optical engine 100 and a semiconductor die 150 is attached to a front side interconnect structure 204 on a substrate 203, in accordance with some embodiments. FIG. 9 illustrates one optical engine 100 and one semiconductor die 150 attached to the front side interconnect structure 204, but multiple optical engines 100 and/or multiple semiconductor dies 150 may be present in other embodiments. The optical engine 100 may be similar to the optical engine 100 shown in FIG. 8. For example, the optical engine 100 may comprise a support 40 with a lens 42 formed therein, in some embodiments.

Prior to attaching the optical engine 100 and the semiconductor die 150, the front side interconnect structure 204 is formed on the substrate 203. The substrate 203 may be a wafer, such as a silicon wafer, in some embodiments. Other substrates, such as a silicon-on-insulator (SOI) substrate, a multi-layered substrate, or a gradient substrate may also be used. The substrate 203 may be doped (e.g., with a p-type or an n-type dopant) or undoped. In some embodiments, the semiconductor material of the substrate 203 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. In other embodiments, the substrate 203 may be a dielectric material such as silicon oxide, glass, ceramic, plastic, or any other suitable material that allows for structural support of overlying devices. For example, the substrate 203 may be a panel, a glass substrate, an organic substrate, a redistribution structure, an interconnect substrate, a core substrate, a printed circuit board (PCB), or the like. In some embodiments, active devices (e.g., transistors, diodes, or the like), passive devices (e.g. capacitors, resistors, or the like), integrated circuits, and/or the like may be formed in the substrate 203. The substrate 203 may be free of passive or active devices, in other embodiments.

In some embodiments, the substrate 203 comprises through vias 206 extending partially or fully into the substrate 203. The through vias 206 are electrically connected to the front side interconnect structure 204. The through vias 206 may be formed, for example, by forming openings extending into the substrate 203. The openings may be formed using acceptable photolithography and etching techniques, such as by forming and patterning a photoresist and then performing an etching process using the patterned photoresist as an etching mask. The etching process may include, for example, a dry etching process and/or a wet etching process. A conductive material may then be formed in the openings, thereby forming the through vias 206. In some embodiments, a liner (not shown) may be deposited in the openings prior to forming the conductive material. The conductive material may comprise, for example, a metal or a metal alloy such as copper, silver, gold, tungsten, cobalt, aluminum, alloys thereof, or the like. A planarization process (e.g., a CMP process or a grinding process) may be performed to remove excess conductive material along the surface of the substrate 203 such that surfaces of the through vias 206 and the substrate 203 are level. Other materials or techniques are possible.

The front side interconnect structure 204 is formed over a front side of the substrate 203 and the through vias 206, and comprises one or more layers of conductive features formed in one or more dielectric layers (not individually illustrated), in some embodiments. The conductive features may comprise conductive lines, conductive vias, conductive pads, metallization patterns, redistribution layers, or the like that provide electrical interconnections and electrical routing. In some embodiments, some conductive features of the front side interconnect structure 204 are physically and electrically coupled to the through vias 206. In some embodiments, the conductive features comprise conductive pads at a top surface of the front side interconnect structure 204. In some embodiments, the front side interconnect structure 204 may have multiple layers of conductive features, but the precise number of layers of conductive features may be dependent upon the design of the front side interconnect structure 204. The conductive features may be formed using any suitable techniques such as deposition, damascene, dual damascene, or the like. The conductive features may include, for example, a metal or a metal alloy such as copper, silver, gold, tungsten, cobalt, ruthenium, aluminum, alloys thereof, combinations thereof, or the like. In some cases, the conductive features may be formed using materials or techniques similar to those described previously for the interconnect structure 20. Other materials or techniques are possible.

Acceptable dielectric materials for the dielectric layers of the front side interconnect structure 204 include oxides such as silicon oxide or aluminum oxide; nitrides such as silicon nitride; carbides such as silicon carbide; the like; or combinations thereof such as silicon oxynitride, silicon oxycarbide, silicon carbonitride, silicon oxycarbonitride or the like. Other dielectric materials may also be used, such as a polymer such as PBO, polyimide, a BCB-based polymer, or the like. The dielectric layers may be formed using any suitable techniques. In some embodiments, the front side interconnect structure 204 may have multiple dielectric layers, but the precise number of dielectric layers may be dependent upon the design of the front side interconnect structure 204. In some cases, the dielectric layers may be formed using materials or techniques similar to those described previously for the interconnect structure 20. Other materials or techniques are possible.

The semiconductor die 150 may comprise, for example, a chip, a die, a system-on-chip (SoC) device, a system-on-integrated-circuit (SoIC) device, the like, or a combination thereof. In some embodiments, the semiconductor die 150 comprises logic dies, memory dies, input-output (I/O) dies, Integrated Passive Devices (IPDs), or the like, or combinations thereof. For example, the semiconductor die 150 may comprise logic dies such as Central Processing Unit (CPU or xPU) dies, Graphic Processing Unit (GPU) dies, mobile application dies, high performance computing (HPC) dies, Micro Control Unit (MCU) dies, BaseBand (BB) dies, Application processor (AP) dies, Application-Specific Integrated Circuit (ASIC) dies, or the like. The semiconductor die 150 may comprise memory dies such as Static Random-Access Memory (SRAM) dies, Dynamic Random-Access Memory (DRAM) dies, High-Bandwidth Memory (HBM) dies, memory cubes, or the like. Other types or configurations of the semiconductor die 150 are possible. The semiconductor die 150 may have conductive connectors, which may be similar to the conductive connectors 64 of the optical engine 100. The semiconductor die 150 may have a height greater than that of the optical engine 100, as shown in FIG. 9, or the semiconductor die 150 may have a height about the same as or less than a height of the optical engine 100.

In some embodiments, the conductive connectors 64 of the optical engine 100 and the conductive connectors of the semiconductor die 150 are placed on corresponding conductive pads of the front side interconnect structure 204. A reflow process is performed to bond the optical engine 100 and the semiconductor die 150 to the front side interconnect structure 204. In this manner, the optical engine 100 and the semiconductor die 150 may be electrically connected to the front side interconnect structure 204. In other embodiments, the optical engine 100 and/or the semiconductor die 150 may be bonded to the front side interconnect structure 204 using dielectric-to-dielectric bonding and/or metal-to-metal bonding (e.g., direct bonding, fusion bonding, oxide-to-oxide bonding, hybrid bonding, or the like). In some embodiments, an underfill 207 may be deposited between the optical engine 100 and the front side interconnect structure 204 and between the semiconductor die 150 and the front side interconnect structure 204.

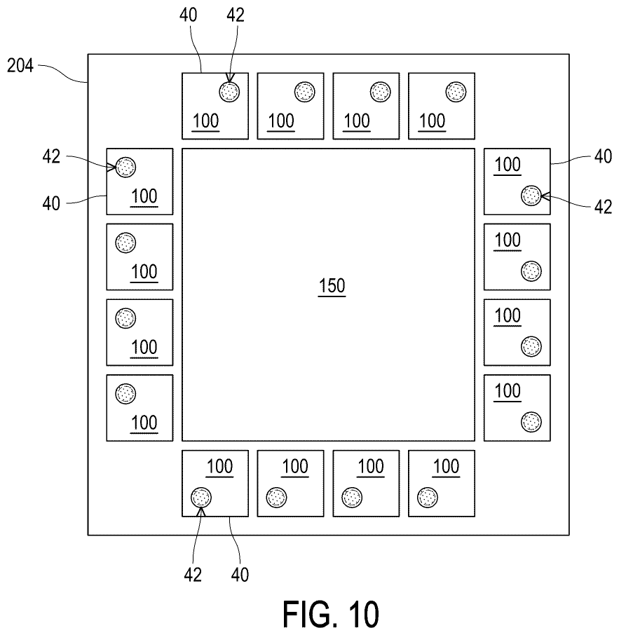

FIG. 10 illustrates a plan view of a semiconductor die 150 and multiple optical engines 100 attached to a front side interconnect structure 204, in accordance with some embodiments. The structure of FIG. 10 may be similar to aspects of the structure of FIG. 9, in some cases. For clarity, some details of the structure may not be shown in FIG. 10. As shown in FIG. 10, multiple optical engines 100 may be attached to the front side interconnect structure 204. The optical engines 100 include lenses 42 formed at the top of supports 40. FIG. 10 illustrates the optical engines 100 in a ring-shaped arrangement around a single semiconductor die 150, but other numbers of optical engines 100, numbers of semiconductor dies 150, or arrangements thereof are possible. In some cases, the optical engines 100 are electrically and communicatively coupled to the semiconductor die 150 by the front side interconnect structure 204. In some cases, the optical engines 100 may function as optical interfaces for the semiconductor die 150. Other configurations are possible.

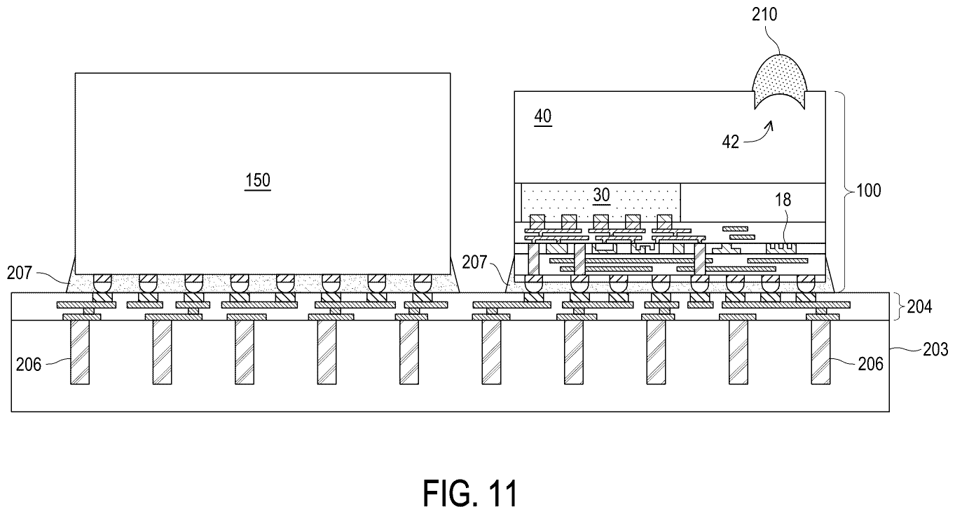

In FIG. 11, a protective coating 210 is formed over the lens 42 of the optical engine 100, in accordance with some embodiments. The protective coating 210 is a temporary material that is deposited over the lens 42 to protect the lens 42 during subsequent processing steps. Accordingly, the protective coating 210 is subsequently removed from the lens 42, described in greater detail below. In some embodiments, the protective coating 210 is deposited such that only the lens 42 is covered and top surfaces of the support 40 are free of the protective coating 210. In other embodiments, the protective coating 210 may also be deposited in the region surrounding the lens 42, such as top surfaces of the support 40 adjacent to the lens 42. In other words, the protective coating 210 may be applied locally to the lens 42 of the optical engine 100. The protective coating 210 may fill the recess of the lens 42. The applied protective coating 210 may have a height above the front side interconnect structure 204 that is greater than, about the same as, or less than a height that of the semiconductor die 150. The protective coating 210 may be a material such as a polymer, a resin, or the like. For example, in some embodiments, the protective coating 210 is an acrylic resin or a novolak resin, though other materials are possible. The protective coating 210 may be applied using a suitable dispensing technique. The protective coating 210 may have other heights, sizes, or shapes than shown in FIG. 11.

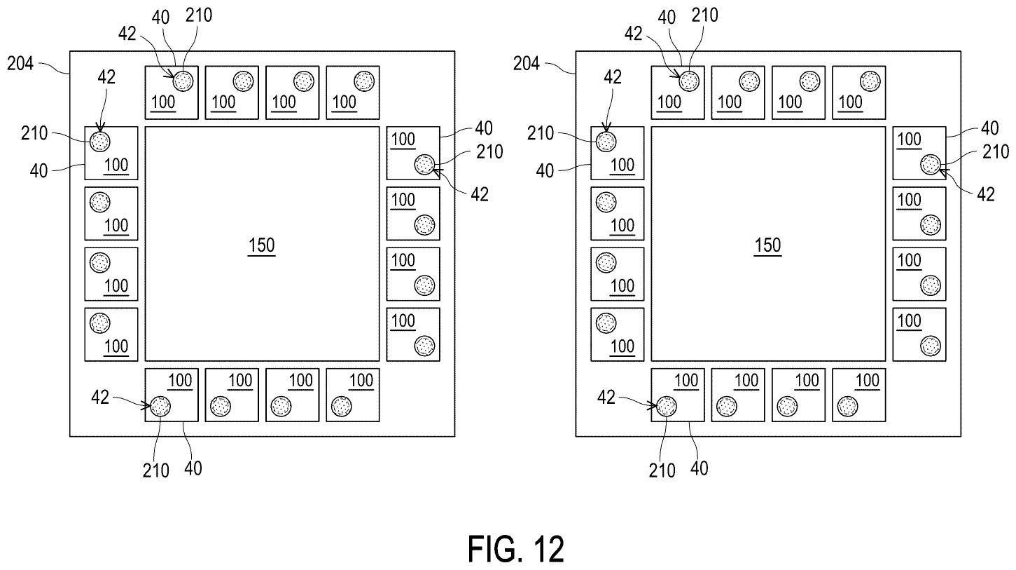

FIG. 12 illustrates a plan view of the structure of FIG. 10 after the protective coating 210 has been applied to the lenses 42 of the optical engines 100, in accordance with some embodiments. As shown in FIG. 12, in some embodiments, a separate region of protective coating 210 may be deposited over each lens 42 of each optical engine 100. For embodiments in which an optical engine 100 includes several lenses 42, a separate region of protective coating 210 may be deposited on each lens 42 or a single region of protective coating 210 may be deposited over two or more lenses 42.

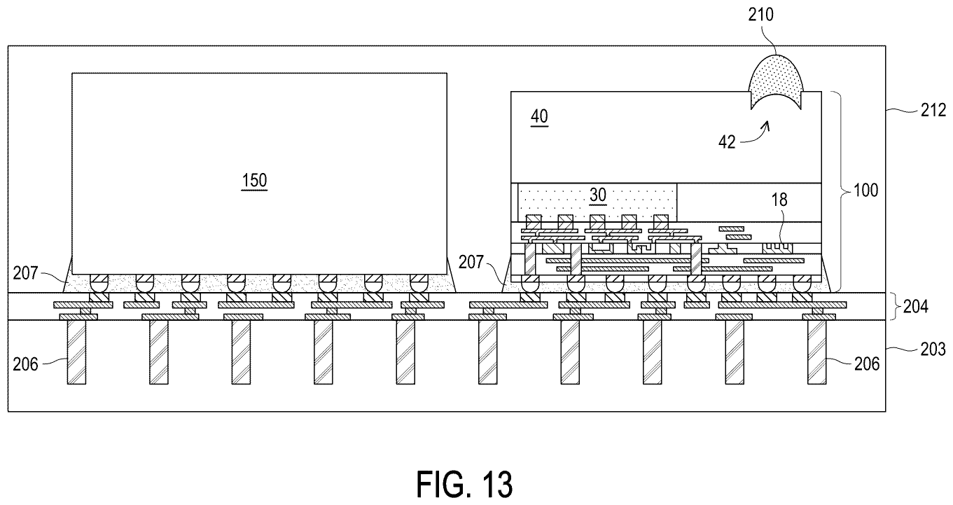

In FIG. 13, an encapsulant 212 is formed on and around the optical engine 100 and the semiconductor die 150, in accordance with some embodiments. The encapsulant 212 may be formed over the front side interconnect structure 204 and may extend between the optical engine 100 and the semiconductor die 150. After formation, the encapsulant 212 encapsulates the optical engine 100 and the semiconductor die 150. The encapsulant 212 may be a molding compound, an epoxy, a polymer, a resin, a composite material, a dielectric material, or the like. For example, in some embodiments, the encapsulant 212 may comprise a material such as 2,2-1,6-Bis(2,3-epoxypropoxy) naphthalene, alicyclic anhydride, or the like, though other materials are possible. In some embodiments, the encapsulant 212 is applied by deposition, spin-on, compression molding, transfer molding, or the like. The encapsulant 212 may be formed over the front side interconnect structure 204 such that the optical engine 100 and the semiconductor die 150 are buried or covered. In some embodiments, the encapsulant 212 also covers the protective coating 210. In some embodiments, the encapsulant 212 may be applied in liquid or semi-liquid form and then subsequently cured. In some embodiments, a planarization process is performed on the encapsulant 212. The planarization process may comprise, for example, a chemical-mechanical polish (CMP) process, a grinding process, an etching process, or the like. In some embodiments, after performing the planarization process, the protective coating 210 remains covered by the encapsulant 212, as shown in FIG. 13. In some embodiments, the planarization process may be omitted.

In FIG. 14, a back side interconnect structure 205 is formed on the substrate 203 to form the interposer structure 202, in accordance with some embodiments. Prior to forming the back side interconnect structure 205, the back side of the substrate 203 may be thinned to expose the through vias 206. The thinning may be performed using an etching process, a CMP process, a grinding process, the like, or a combination thereof. The back side interconnect structure 205 may comprise one or more layers of conductive features formed in one or more dielectric layers (not individually illustrated). The back side interconnect structure 205 is formed over a back side of the substrate 203 and through vias 206 such that conductive features of the back side interconnect structure 205 are physically and electrically coupled to the through vias 206. The conductive features and dielectric layers of the back side interconnect structure 205 may be similar to the conductive features and dielectric layers of the front side interconnect structure 204, and may be formed using similar materials or techniques. In some embodiments, the back side interconnect structure 205 may have multiple layers of conductive features or dielectric layers, but the precise number may be dependent upon the design of the back side interconnect structure 205. In some embodiments, the conductive features of the back side interconnect structure 205 includes UBMs or the like at a bottom surface of the back side interconnect structure 205. In some embodiments, conductive connectors 208 are formed on conductive features of the back side interconnect structure 205, such as on UBMs of the back side interconnect structure 205. The conductive connectors 208 may be similar to the conductive connectors 64 described previously. For example, the conductive connectors 208 may comprise solder bumps or the like.

In FIG. 15, a planarization process is performed on the encapsulant 212 to expose the protective coating 210, in accordance with some embodiments. In this manner, a package component 200 may be formed. The planarization process may comprise, for example, a CMP process, a grinding process, or the like. The planarization process may expose a top surface of the semiconductor die 150, in some embodiments. After performing the planarization process, the encapsulant 212 may remain extending over a top surface of the optical engine 100, in some embodiments. In other embodiments, the semiconductor die 150 may remain covered by the encapsulant 212, and/or a top surface of the optical engine 100 may be exposed. The planarization process may remove an upper portion of the protective coating 210, with the lens 42 remaining covered by the remaining protective coating 210. In some embodiments, after performing the planarization process, top surfaces of the encapsulant 212, the protective coating 210, the semiconductor die 150, and/or the optical engine 100 may be substantially level or coplanar (within process variations). In some embodiments, after performing the planarization process, a thickness T1 of the encapsulant 212 over the optical engine 100 may be in the range of about 10 μm to about 100 μm, though other thicknesses are possible. In some cases, the planarization process is controlled to adjust the thickness T1 of the remaining encapsulant 212 in order to accommodate the shape of an overlying optical fiber coupler or the like, described in greater detail below.

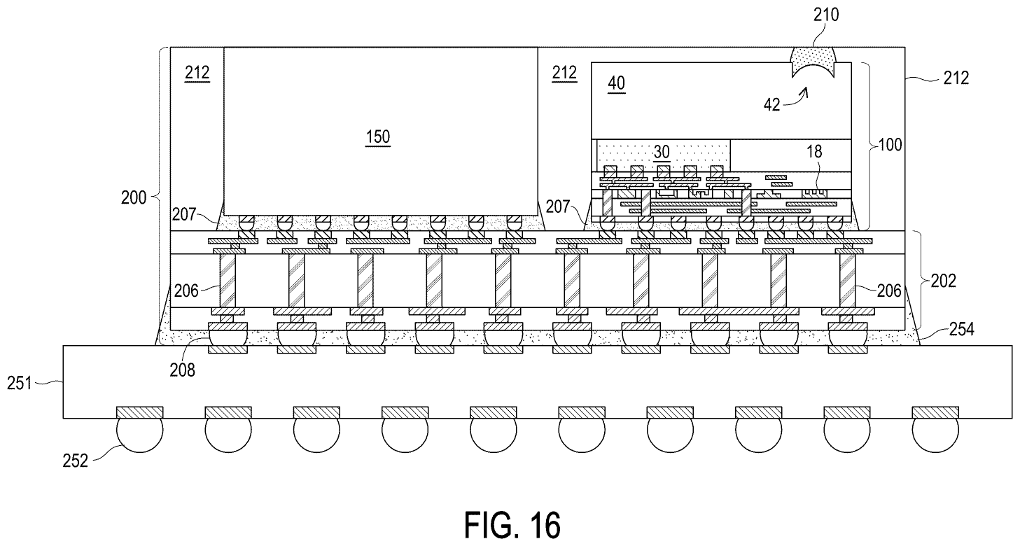

FIGS. 16 through 20 illustrate intermediate stages in the formation of a package 250 comprising a package component 200, in accordance with some embodiments. The package component 200 of the package 250 may be similar to the package component 200 described for FIG. 15. In some cases, the package 250 may be considered a photonic package, a 3DIC structure, or the like.

In FIG. 16, the package component 200 is attached to a package substrate 251, in accordance with some embodiments. During the attachment of the package component 200, the protective coating 210 remains covering the lens 42, in some embodiments. In some embodiments, the package substrate 251 comprises conductive pads, conductive routing, and/or other conductive features that provide interconnections and electrical routing. In some embodiments, the package substrate 251 may comprise an interposer, a semiconductor substrate, a redistribution structure, an interconnect substrate, a core substrate, a printed circuit board (PCB), or the like. In some embodiments, the package substrate 251 comprises active and/or passive devices. In other embodiments, the package substrate 251 is free of active and/or passive devices. In some embodiments, conductive connectors 252 are formed on the package substrate 251. The conductive connectors 252 may be similar to the conductive connectors 208 or conductive connectors 64 described previously, and may be formed using similar materials or techniques. For example, the conductive connectors 252 may comprise solder bumps or the like.

In some embodiments, the conductive connectors 208 of the package component 200 are placed on corresponding conductive pads of the package substrate 251 and then a reflow process is performed to bond the package component 200 to the package substrate 251. In this manner, the package component 200 may be electrically connected to the package substrate 251 In other embodiments, the package component 200 may be bonded to the package substrate 251 using dielectric-to-dielectric bonding and/or metal-to-metal bonding (e.g., direct bonding, fusion bonding, oxide-to-oxide bonding, hybrid bonding, or the like). In some embodiments, an underfill 254 may be deposited between the package component 200 and the package substrate 251.

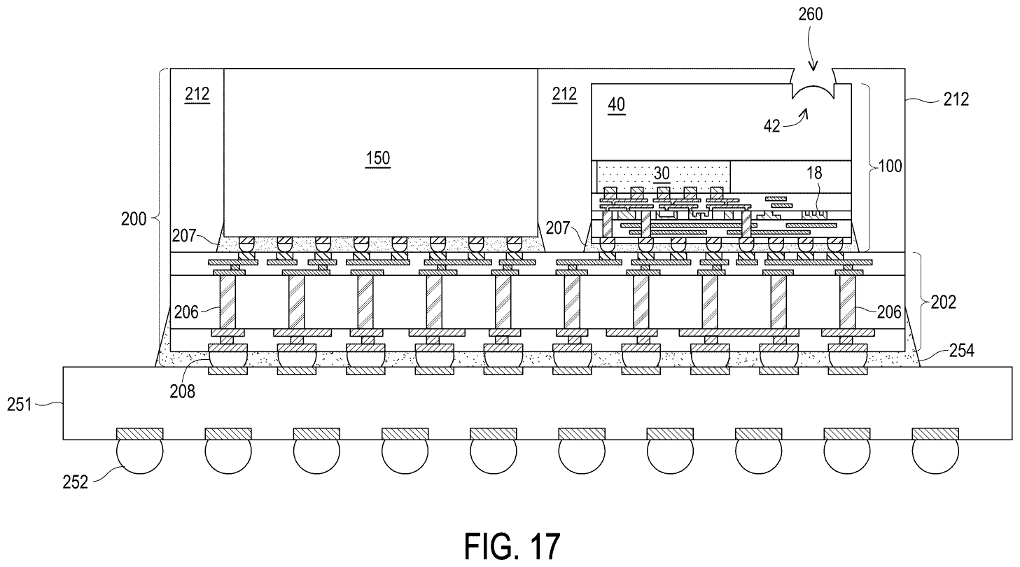

In FIG. 17, an etching process is performed to remove the protective coating 210 and expose the lens 42, in accordance with some embodiments. Removing the protective coating 210 forms an opening 260 in the encapsulant that exposes the lens 42. In some embodiments, the etching process may selectively etch the protective coating 210 without significantly etching other exposed materials of the package component 200 or package substrate 251. For example, the etching process may etch the material of the protective coating 210 at a greater rate than the material of the encapsulant 212. In some embodiments, the etching selectivity of the protective coating 210 with respect to the encapsulant 212 may be in the range of about 10:1 to about 100:1, though other selectivities are possible. In some embodiments, the etching process is a wet etch comprising one or more suitable etchants such as propylene glycol monomethyl ether, propylene glycol monomethyl ether acetate, diethylene glycol monomethyl ether, 3-methoxy-3-methyl-1-butanol, tetramethylammonium hydroxide (TMAH), the like, or a combination thereof. Other etchants are possible, and the particular etchant(s) used, the particular combination of etchants used, and/or the particular ratio of etchants used may depend on the particular materials of the protective coating 210 and encapsulant 212. In some cases, forming a temporary protective coating 210 over the lens 42 that can be removed to expose the lens 42 can reduce the risk of damaging the lens 42. For example, other techniques to expose the lens 42, such as etching encapsulant 212 covering the lens 42, may be more likely to result in lens 42 damage than the use of a protective coating 210 as described herein.

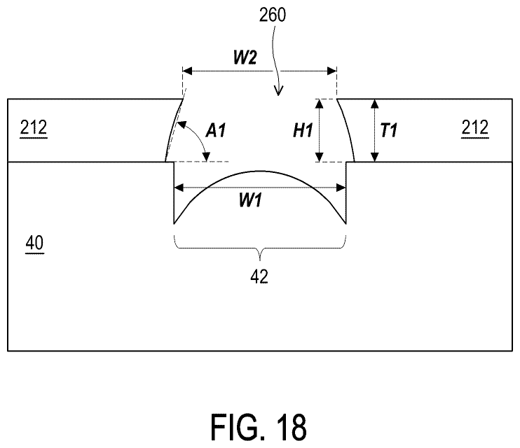

FIG. 18 illustrates a magnified view of a lens 42 in a support 40 exposed by an opening 260 in an overlying encapsulant 212, in accordance with some embodiments. The region around the lens 42 of the magnified view of FIG. 18 may be similar to the region around the lens 42 of FIG. 17, for example. As shown in FIG. 18, the encapsulant 212 over the support 40 and near the lens 42 may have a thickness T1, which may be similar to the thickness T1 described previously for FIG. 15. Accordingly, the opening 260 may have a height H1 (e.g., a “step height”) that is about the same as the thickness T1. As shown in FIG. 18, the opening 260 in the encapsulant 212 may have angled or curved sidewalls, in some embodiments. In some embodiments, the sidewalls of the opening 260 may have an approximate angle A1 that is in the range of about 60° to about 85°, though other angles are possible. In other embodiments, the sidewalls of the opening 260 may be substantially vertical or substantially straight. As shown in FIG. 18, the opening 260 may have multiple widths due to a non-vertical sidewall profile of the opening 260. In some embodiments, the top of the opening 260 (e.g., near a top surface of the encapsulant 212) may have a smaller width than the bottom of the opening 260 (e.g., near a bottom surface of the encapsulant 212). In other words, the opening 260 may taper upwards. In some cases, the top of the opening 260 may have a width W2 that is greater than, less than, or about the same as the width W1 of the lens 42. In some cases, the middle or bottom of the opening 260 may have a width that is greater than, less than, or about the same as the width W2 or the width W1 of the lens 42. In some embodiments, top surfaces of the support 40 adjacent the lens 42 may be exposed by the opening 260, as shown in FIG. 18. In other embodiments, top surfaces of the support 40 adjacent the lens 42 are covered by the encapsulant 212. In some cases, portions of the encapsulant 212 may overhang the lens 42. The width, sidewall profile, and shape of the opening 260 may be controlled by controlling the deposition of the protective coating 210. The height H1 of the opening 260 may be controlled by controlling the planarization process that exposes the protective coating 210.

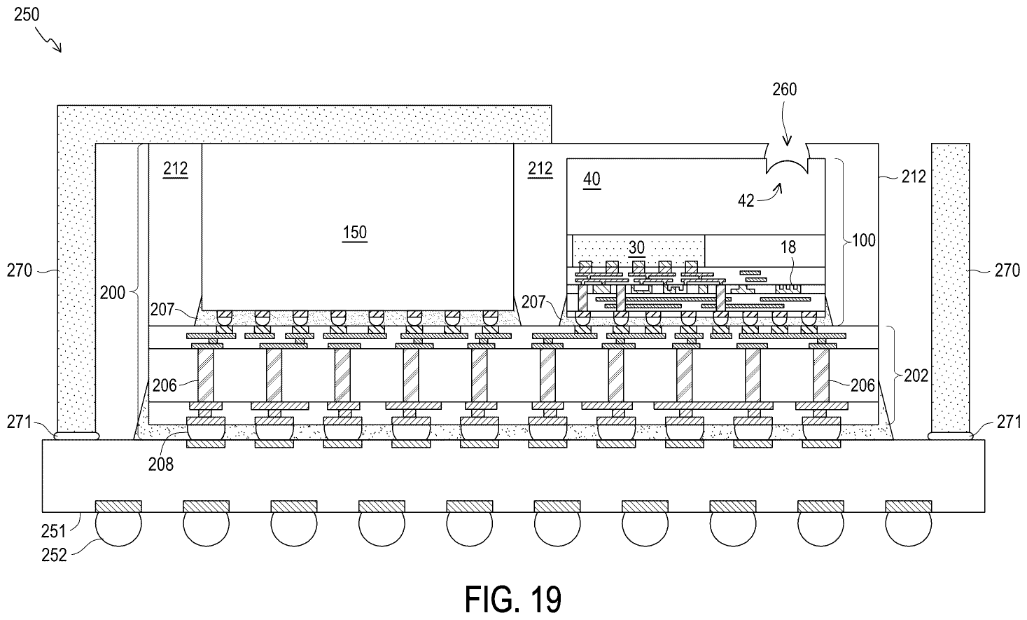

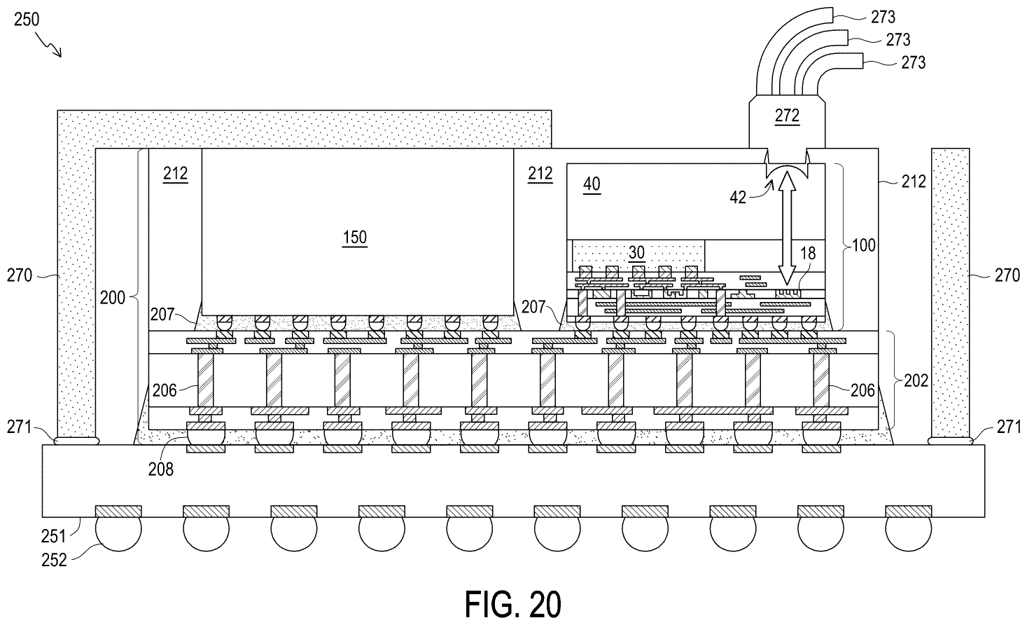

In FIG. 19, a lid 270 is attached to the structure to form a package 250, in accordance with some embodiments. The lid 270 may comprise a suitable material such as metal, ceramic, polymer, composite, dielectric, or a combination thereof. The lid 270 may be attached using, for example, an adhesive, epoxy, glue, or the like. For example, as shown in FIG. 19, the lid 270 may be attached to the package substrate 251 by an adhesive 271. In some embodiments, the lid 270 extends over the encapsulant 212 and/or the semiconductor die 150 of the package component 200. The lid 270 may fully cover the semiconductor die 150, in some cases. In other embodiments, the lid 270 extends over the optical engine 100 of the package component 200. In some embodiments, an adhesive, a thermal interface material (TIM), or the like (not illustrated) may be present between the package component 200 and the lid 270. In some embodiments, the lid 270 has an opening over the lens 42 to allow for the subsequent attachment of a fiber coupler 272 or the like (see FIG. 20). The lid 270 may protect the package 250 and also may facilitate heat dissipation from the package component 250, in some cases. Accordingly, the lid 270 may be considered a heat sink or the like, in some cases.

In FIG. 20, a fiber coupler 272 is attached to the package 250, in accordance with some embodiments. The fiber coupler 272 facilitates the optical coupling of one or more optical fibers 273 with the package 250. In some embodiments, the fiber coupler 272 may comprise a fiber array unit (FAU), a ferrule, a fiber assembly, or the like. The fiber coupler 272 may be positioned over the lens 42 of the package component 200 and attached to the package component 200 using an adhesive, an optical glue, an index matching gel, or the like. For example, in some cases, an adhesive, an optical glue, an index matching gel, or the like may be deposited on the lens 42 and/or on the encapsulant 212 prior to attachment of the fiber coupler 272.

In some embodiments, the height H1 of the opening 260 may be controlled to provide an appropriate distance between the lens 42 and the fiber coupler 272 for efficient optical coupling between the lens 42 and the fiber coupler 272. In some embodiments, a portion of the fiber coupler 272 protrudes into the opening 260. In this manner, the fiber coupler 272 may extend closer to the lens 42, which in some cases can improve optical coupling between the fiber coupler 272 and the lens 42. In some embodiments, the width W1 and/or the height H1 of the opening 260 (see FIG. 18) may be controlled to correspond to the dimensions of the portion of the fiber coupler 272 that protrudes into the opening 260. In other words, a size or shape of the opening 260 may be determined from a corresponding size, shape, or optical characteristic of the fiber coupler 272. In some cases, the opening 260 may be formed having specific dimensions that corresponds to a specific fiber coupler 272. In this manner, the size or shape of the opening 260 may provide improve attachment of the fiber coupler 272 to the package 250 or may provide more efficient optical coupling between the fiber coupler 272 and the lens 42. In some embodiments, the fiber coupler 272 may extend below a top surface of the support 40. In other embodiments, the fiber coupler 272 does not extend below a top surface of the encapsulant 212. In some embodiments, the characteristics of the fiber coupler 272, the opening 260, and/or the lens 42 of a package 250 may be designed in coordination to provide improved optical coupling efficiency.

The fiber coupler 272 allows for external optical communication with the package 250. For example, the fiber coupler 272 may couple optical signals from one or more optical fibers 273 into the lens 42. The optical signals (represented by the dashed arrow in FIG. 20) may be transmitted from the lens 42, through various layers of the optical engine 100, and into a photonic component 18 of the optical engine 100. In some embodiments, the photonic component 18 may be a grating coupler or the like that couples the optical signals into waveguides or other photonic components of the optical engine 100. Similarly, optical signals may be transmitted from a photonic component 18 to the lens 42, from the lens 42 into the fiber coupler 272, and from the fiber coupler 272 into one or more optical fibers 273. In this manner, the fiber coupler 272 and the lens 42 facilitate optical communication between the optical engine 100 and optical fibers 273.

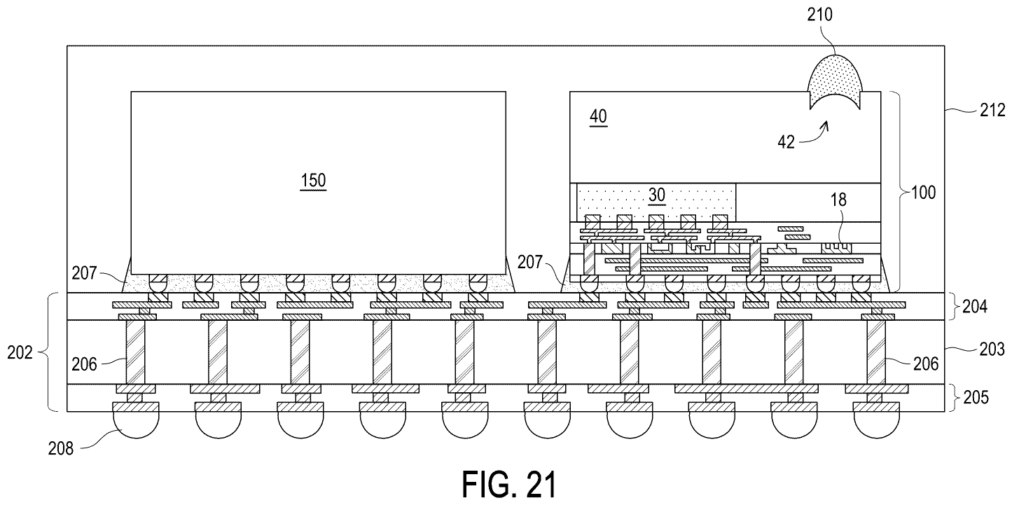

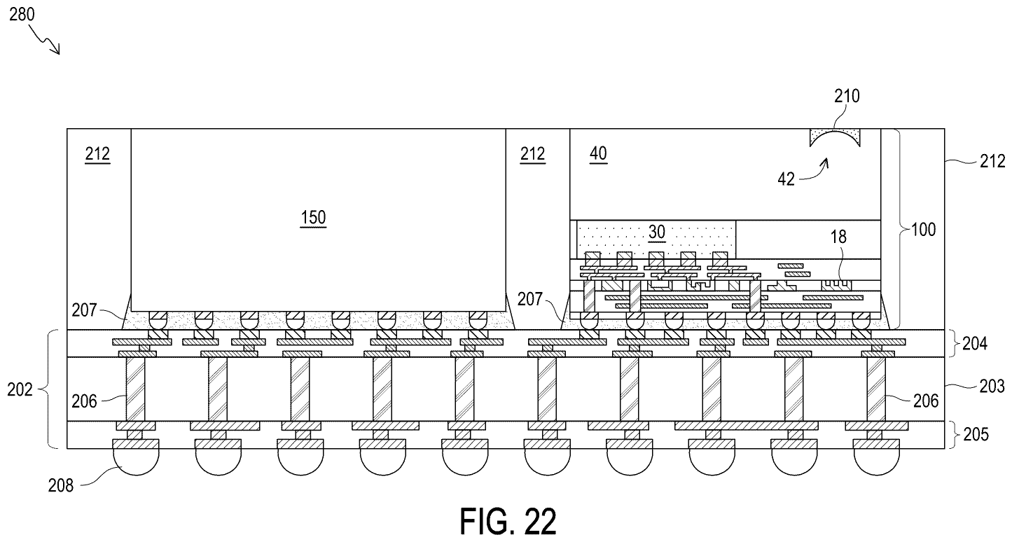

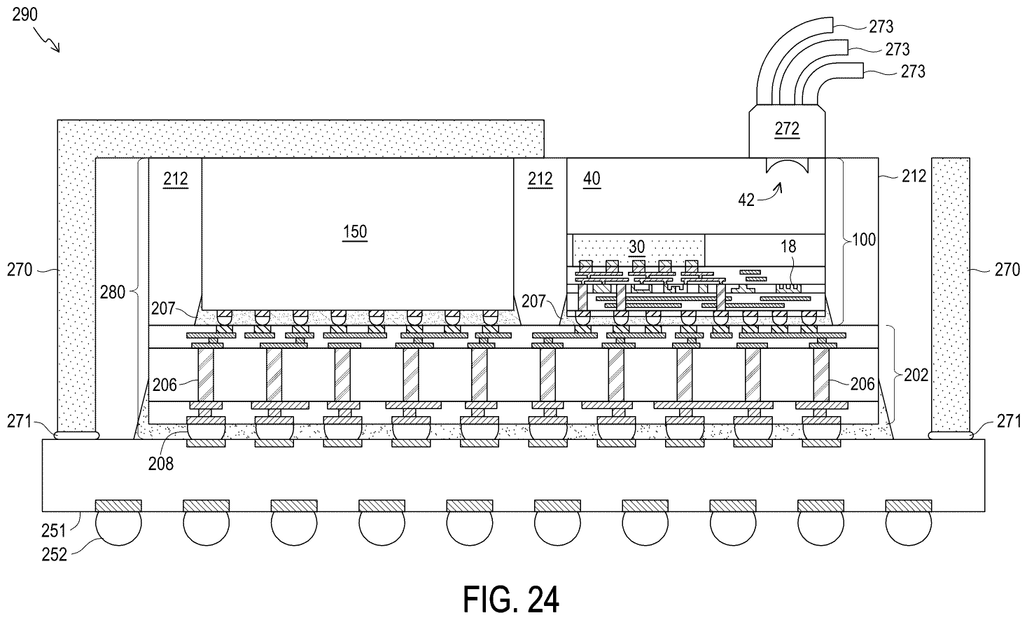

FIGS. 21 through 24 illustrate intermediate stages in the formation of a package 290 (see FIG. 24) comprising a package component 280 (see FIG. 22), in accordance with some embodiments. The package component 280 is similar to the package component 200 described previously, except that the encapsulant 212 is removed from a top surface of the optical engine 100. The package component 280 may be formed using some materials, techniques, and/or process steps that are similar to those used to form the package component 200. The package 290 is similar to the package 250, and may be formed using similar materials, techniques, or process steps. Accordingly, some details may not be repeated in the following discussion.

FIG. 21 illustrates a structure similar to that shown in FIG. 14, in accordance with some embodiments. For example, FIG. 21 illustrates a semiconductor die 150 and an optical engine 100 attached to an interposer structure 202. The semiconductor die 150 and the optical engine 100 may be similar to those described previously. For example, the optical engine 100 comprises a support 40 with a lens 42 formed therein. A protective coating 210 is formed over the lens 42, which may be similar to the protective coating 210 described previously. An encapsulant 212 has been formed over the interposer structure 202, the semiconductor die 150, and the optical engine 100. As shown in the structure of FIG. 21, the encapsulant 212 may cover the protective coating 210.

In FIG. 22, a planarization process is performed on the encapsulant 212 to expose the semiconductor die 150 and the optical engine 100, in accordance with some embodiments. In this manner, a package component 280 may be formed. The planarization process may be similar to that described previously for FIG. 15. For example, the planarization process may include a CMP process, grinding process, and etching process, the like, or a combination thereof. The planarization process may remove upper portions of the protective coating 210 and may expose top surfaces of the semiconductor die 150 and the support 40 of the optical engine 100. After performing the planarization process, top surfaces of the encapsulant 212, the semiconductor die 150, the optical engine 100 (e.g., top surfaces of the support 40), and the protective coating 210 may be level or coplanar. In other embodiments, the semiconductor die 150 may remain covered by the encapsulant 212 after performing the planarization process.

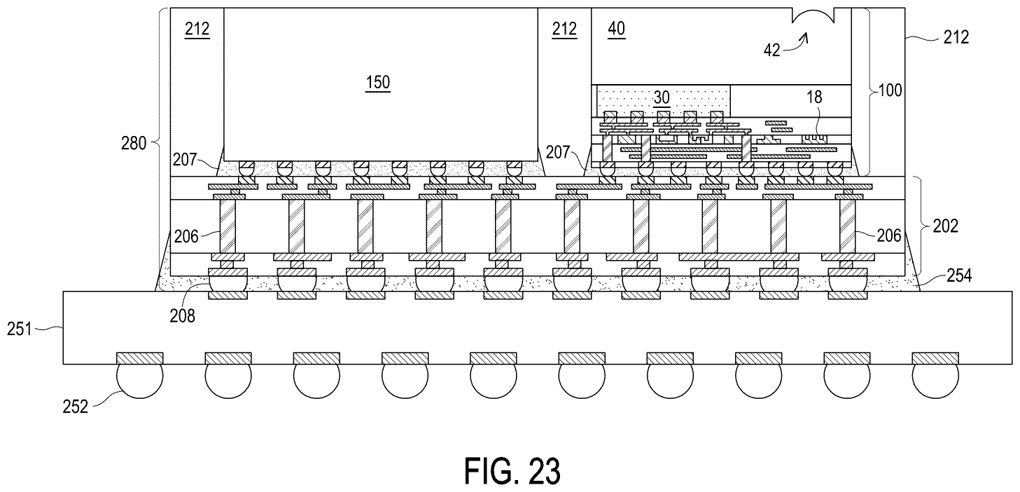

In FIG. 23, the package component 280 is attached to a package substrate 251, and the protective coating 210 is removed, in accordance with some embodiments. The package substrate 251 may be similar to the package substrate 251 described previously for FIG. 16, and the package component 280 may be attached in a similar manner. The protective coating 210 may be removed using an etching process similar to that described previously for FIG. 17. For example, the protective coating 210 may be removed using a selective wet etching process. Removing the protective coating 210 exposes the lens 42 of the optical engine 100.

In FIG. 24, a lid 270 and a fiber coupler 272 are attached to form a package 290, in accordance with some embodiments. The lid 270 may be similar to the lid 270 described previously for FIG. 19, and may be attached using similar techniques. For example, the lid 270 may extend over the encapsulant 212 and the semiconductor die 150. The lid 270 may extend completely over the semiconductor die 150, which can facilitate heat dissipation from the semiconductor die 150, in some embodiments. In the embodiment of FIG. 24, the lid 270 does not extend over the optical engine 100. The fiber coupler 272 may be similar to the fiber coupler 272 described previously for FIG. 20. For example, the fiber coupler 272 may be located over the lens 42 to facilitate optical coupling of optical fibers 273 to the optical engine 100. Because the top surface of the optical engine 100 is not covered by the encapsulant 212 in the embodiment of FIG. 24, the fiber coupler 272 is attached to a top surface of the support 40. In other embodiments, a portion of the fiber coupler 272 may extend below a top surface of the support 40.

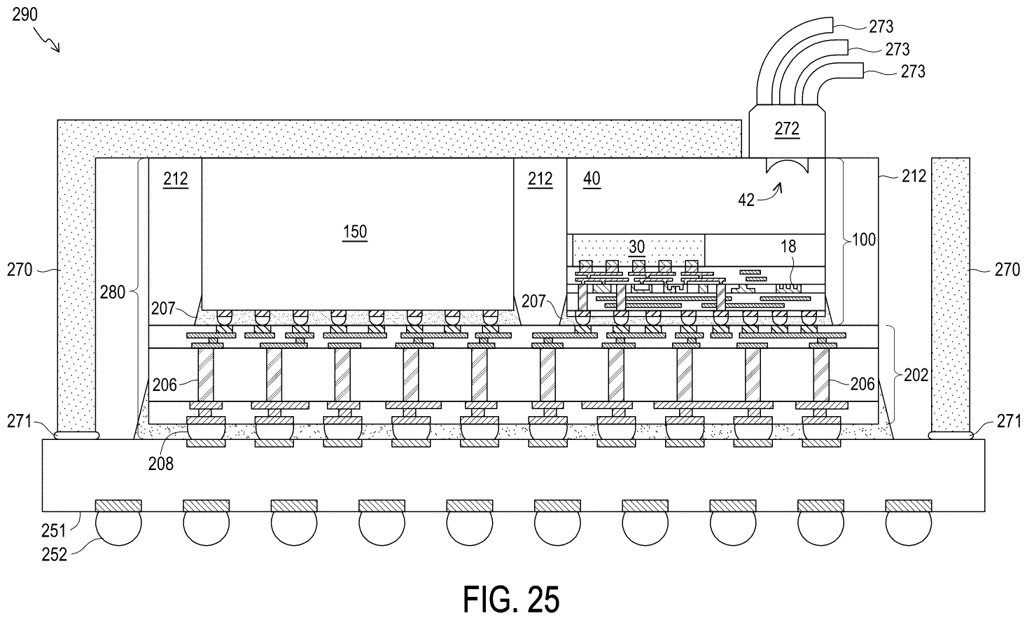

FIG. 25 illustrates a package 290 similar to the package 290 of FIG. 24, except that the lid 270 extends on a top surface of the optical engine 100. The lid 270 also extends over the semiconductor die 150, similar to the package 290 of FIG. 24 or the package 250 of FIG. 20. In some embodiments, having the lid 270 extend on the optical engine 100 can allow the lid 270 to more efficiently dissipate heat from the optical engine 100. In this manner, the lid 270 may dissipate heat from the semiconductor die 150 and the optical engine 100, which can improve thermal performance of the package component 280 and/or the package 290. In some embodiments, a TMI or the like (not illustrated) may be present between the optical engine 100 and the lid 270. The lid 270 may physically contact the fiber coupler 272, in some embodiments.

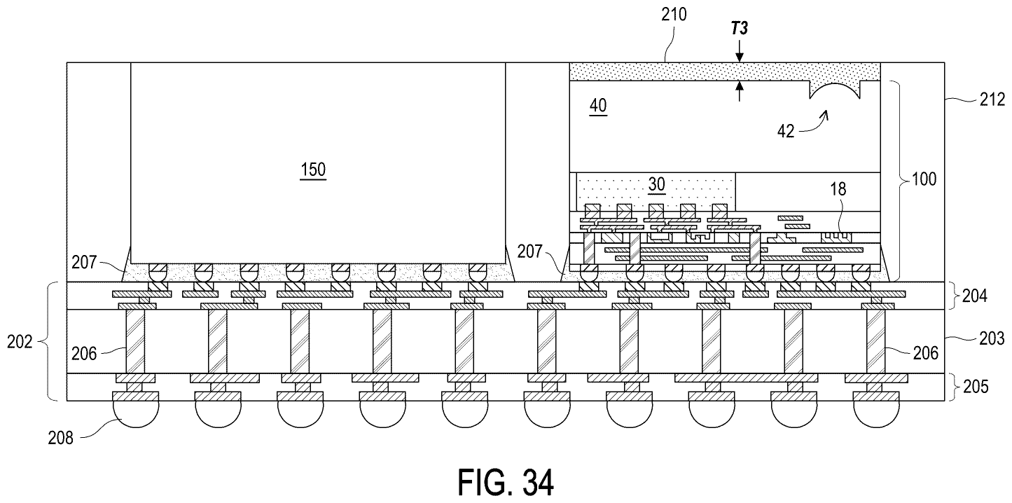

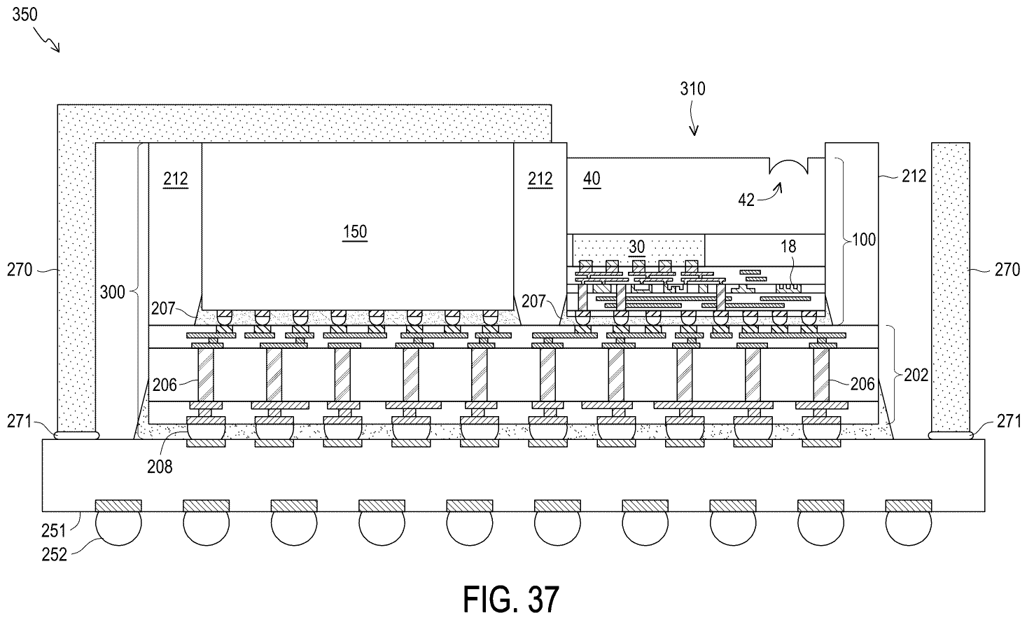

FIGS. 26 through 38 illustrate intermediate stages in the formation of a package 350 (see FIG. 37) comprising a package component 300 (see FIG. 34), in accordance with some embodiments. The package component 300 is similar to the package component 200 described previously, except that the protective coating 210 fully covers the top surface of the optical engine 100. The package component 300 may be formed using some materials, techniques, and/or process steps that are similar to those used to form the package component 200. The package 350 is similar to the package 250, and may be formed using similar materials, techniques, or process steps. Accordingly, some details may not be repeated in the following discussion.

FIGS. 26 through 29 illustrate the formation of an optical engine 100 with a protective coating 210, in accordance with some embodiments. The optical engine 100 is similar to the optical engine 100 described previously for FIGS. 1-8, and may be formed using similar techniques. In FIGS. 26-29, the optical engines 100 are formed on the same substrate or carrier and then singulated to form individual optical engines 100. The optical engine 100 of FIGS. 1-8 and the optical engines 100 of FIGS. 26-29 may be formed using similar materials, techniques, or process steps. Accordingly, some details may not be repeated in the following discussion.

FIG. 26 illustrates a structure comprising multiple optical engines 100 prior to singulation, in accordance with some embodiments. For example, the structure shown in FIG. 26 has multiple regions 100 where respective optical engines 100 are formed. The regions 100 may be separated by scribe regions (not illustrated) that are removed during singulation. The optical engines 100 may be formed on a single wafer or substrate (e.g., substrate 10) using process steps similar to those described previously for FIGS. 1-8. For example, a single support structure 40′ may be formed over the regions 100 that subsequently forms the supports 40 of the optical engines 100 during singulation. A lens 42 is formed in the support structure 40′ in each region 100. The lens 42 may be similar to the lens 42 described previously.

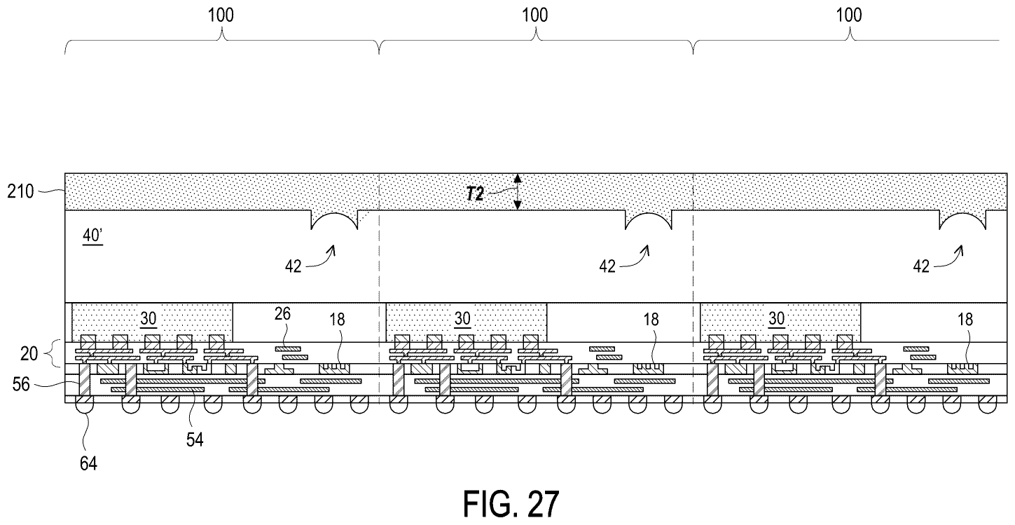

In FIG. 27, a protective coating 210 is deposited over the support structure 40′, in accordance with some embodiments. The protective coating 210 may be similar to the protective coating 210 described for FIG. 11. For example, the protective coating 210 covers and protects the lenses 42, and the protective coating 210 may comprise a polymer, a resin, or the like. The protective coating 210 may be deposited to fully cover the top surfaces of the regions 100, and thus each optical engine 100 is covered by the protective coating 210. Accordingly, the protective coating 210 may be deposited using a technique that forms a continuous layer over the structure, such as a spin-on technique (e.g., spin coating) or the like.

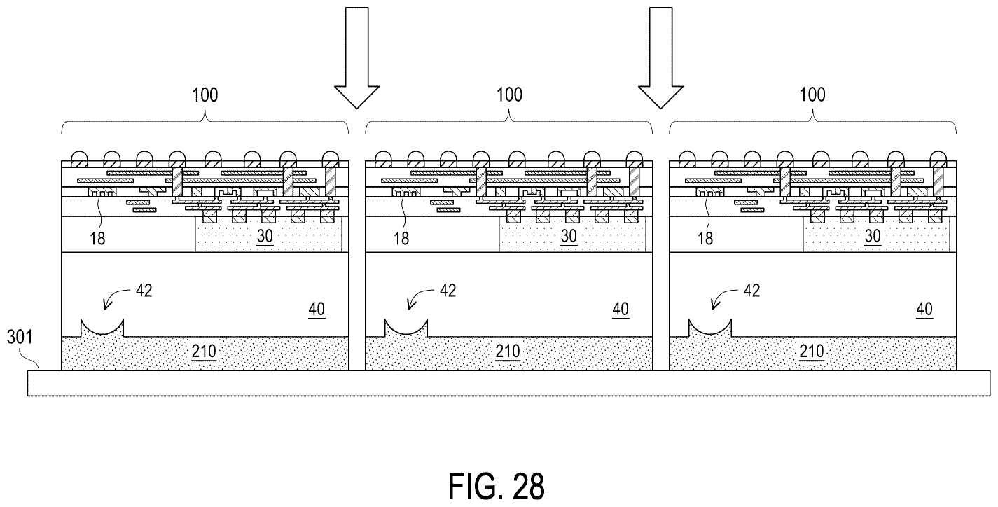

In FIG. 28, the structure is singulated into individual optical engines 100, in accordance with some embodiments. For example, the structure may be flipped over and the protective coating 210 may be attached to a carrier 301. The carrier 301 may be, for example, a die attach film (DAF), a tape, a wafer, a panel, a glass substrate, the like, or another type of carrier. The singulation process may include a mechanical sawing process, a laser process, a plasma dicing process, an etching process, or any other suitable singulation process. After performing the singulation process, the structure has been separated into individual optical engines 100. The singulation process separates the support structure 40′ into supports 40, and separates the protective coating 210 such that each optical engine 100 is covered by the protective coating 210. Other singulation processes or process steps are possible.

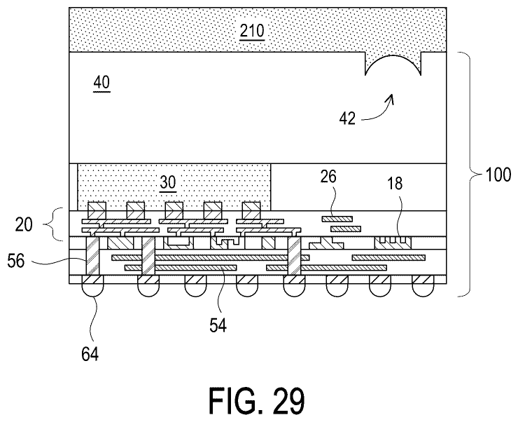

A single singulated optical engine 100 is shown in FIG. 29, in accordance with some embodiments. The optical engine 100 of FIG. 29 may be similar to the optical engine 100 of FIG. 8, except that the optical engine 100 of FIG. 29 is covered by the protective coating 210. The protective coating 210 fully covers the support 40, including covering the lens 42. In some cases, sidewalls of the protective coating 210 and the optical engine 100 may be coterminous or coplanar. For example, sidewalls of the protective coating 210 and sidewalls of the support 40 may be coterminous or coplanar. The optical engine 100 of FIG. 29 is an example, and other configurations are possible. For example, in other embodiments, an optical engine 100 may have multiple lenses 42 that are covered by the same protective coating 210.

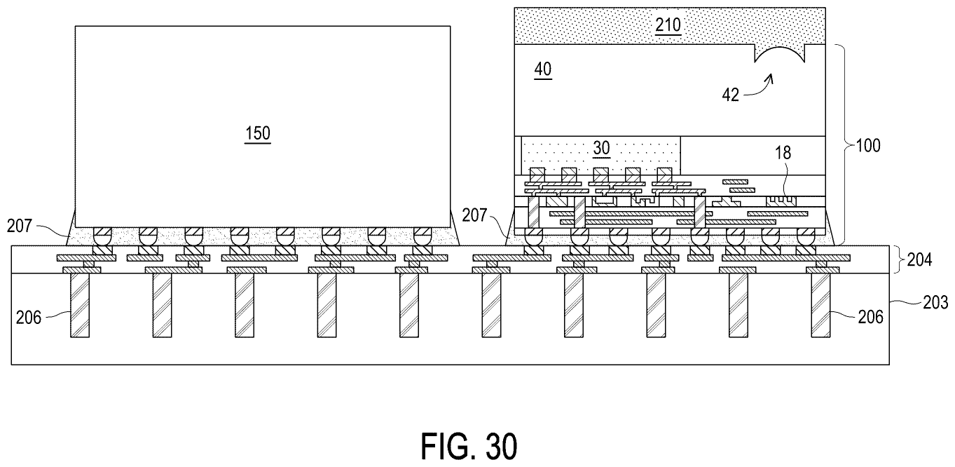

FIGS. 30 through 34 illustrate the formation of a package component 300, in accordance with some embodiments. The package component 300 is similar to the package component 200 described previously for FIGS. 9-15, except the top side of the optical engine 100 is covered by the protective coating 210. The package component 200 of FIGS. 9-15 and the package component 300 of FIGS. 30-34 may be formed using similar materials, techniques, or process steps. Accordingly, some details may not be repeated in the following discussion.

In FIG. 30, an optical engine 100 and a semiconductor die 150 is attached to a front side interconnect structure 204 on a substrate 203, in accordance with some embodiments. The semiconductor die 150, the front side interconnect structure 204, and the substrate 203 may be similar to those described previously for FIG. 9. For example, in some embodiments, the substrate 203 comprises through vias 206 extending into the substrate 203 that are electrically connected to the front side interconnect structure 204. The optical engine 100 and the semiconductor die 150 may be attached to the front side interconnect structure 204 using a technique similar to that described for FIG. 11. For example, the optical engine 100 and the semiconductor die 150 may be placed on the front side interconnect structure 204, and then a reflow process may be performed. The structure shown in FIG. 30 is an example, and other configurations are possible. For example, another number of optical engines 100 or semiconductor dies 150 may be attached. In some embodiments, a height of the protective coating 210 above the front side interconnect structure 204 may be greater than a height of the semiconductor die 150 above the front side interconnect structure 204. In other embodiments the protective coating 210 may have a height that is about the same as or less than a height of the semiconductor die 150.

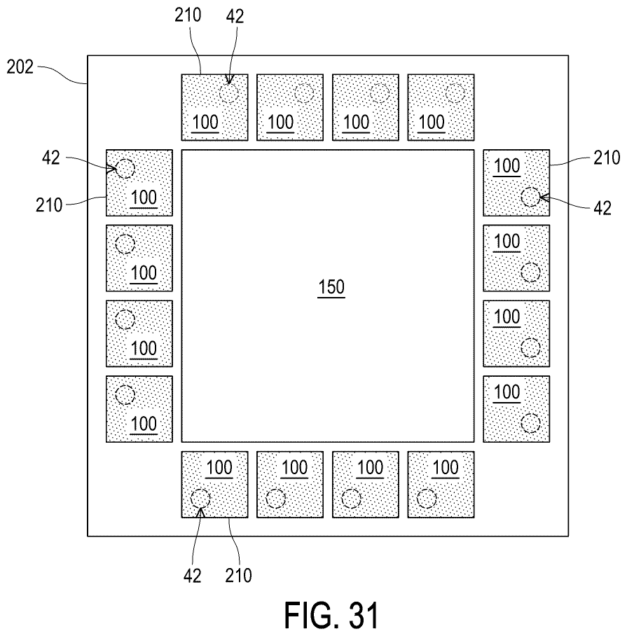

FIG. 31 illustrates a plan view of a semiconductor die 150 and multiple optical engines 100 attached to a front side interconnect structure 204, in accordance with some embodiments. The structure shown in FIG. 31 may be similar to the structure shown in FIG. 10, in some cases. Further, the structure of FIG. 31 may be similar to aspects of the structure of FIG. 30, in some cases. For clarity, some details of the structure may not be shown in FIG. 31. As shown in FIG. 31, multiple optical engines 100 may be attached to the front side interconnect structure 204. The optical engines 100 include lenses 42 at their top surfaces. The optical engines 100 of FIG. 31 may be formed using the techniques described for FIGS. 26-29. Accordingly, the top surface of each optical engine 100 is covered by the protective coating 210. FIG. 31 is an example, and other configurations or arrangements are possible.

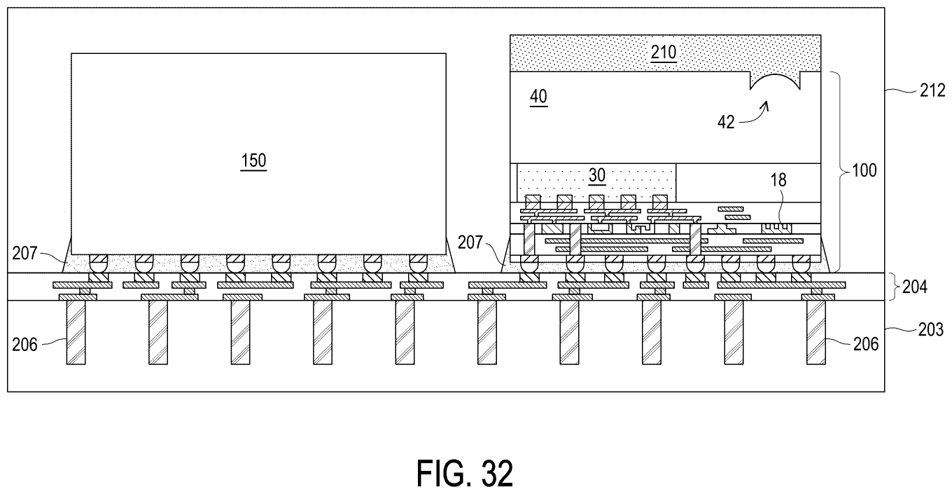

In FIG. 32, an encapsulant 212 is formed on and around the optical engine 100 and the semiconductor die 150, in accordance with some embodiments. The encapsulant 212 may be similar to the encapsulant 212 described previously for FIG. 13. For example, the encapsulant 212 may be formed over the front side interconnect structure 204 such that the optical engine 100 and the semiconductor die 150 are buried or covered. In some embodiments, the encapsulant 212 also covers the protective coating 210. In some embodiments, a planarization process (e.g., a CMP process, a grinding process, or the like) is performed on the encapsulant 212 and the protective coating 210 remains covered by the encapsulant 212 after the planarization process, as shown in FIG. 32. In some embodiments, the planarization process may be omitted.

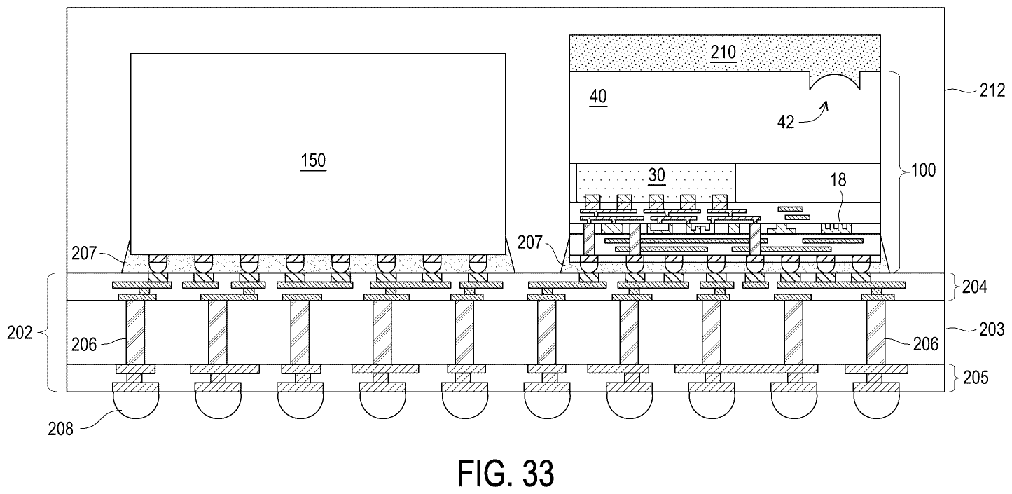

In FIG. 33, a back side interconnect structure 205 is formed on the substrate 203 to form an interposer structure 202, in accordance with some embodiments. The back side interconnect structure 205 may be similar to the back side interconnect structure 205 described previously for FIG. 14, and may be formed using similar techniques. For example, prior to forming the back side interconnect structure 205, the back side of the substrate 203 may be thinned to expose the through vias 206. Conductive connectors 208 may be formed on the back side interconnect structure 205, which may be similar to the conductive connectors 208 described previously.

In FIG. 34, a planarization process is performed on the encapsulant 212 to expose the protective coating 210, in accordance with some embodiments. In this manner, a package component 300 may be formed. The planarization process may be similar to the planarization process described previously for FIG. 15. For example, the planarization process may comprise a CMP process, a grinding process, or the like. The planarization process may also expose a top surface of the semiconductor die 150, in some embodiments. The planarization process may remove an upper portion of the protective coating 210, with optical engine 100 remaining covered by the remaining protective coating 210. In this manner, the planarization process may thin the protective coating 210. After performing the planarization process, the protective coating 210 may have a thickness T3 that is in the range of about 10 μm to about 300 μm, though other thicknesses are possible. The thickness T3 may be controlled by controlling the amount of protective coating 210 removed by the planarization process. In some embodiments, after performing the planarization process, top surfaces of the encapsulant 212, the protective coating 210, and/or the semiconductor die 150 may be substantially level or coplanar (within process variations). In some cases, the planarization process is controlled to adjust the thickness T3 of the remaining protective coating 210 in order to accommodate the shape of an overlying optical fiber coupler or the like, described in greater detail below.

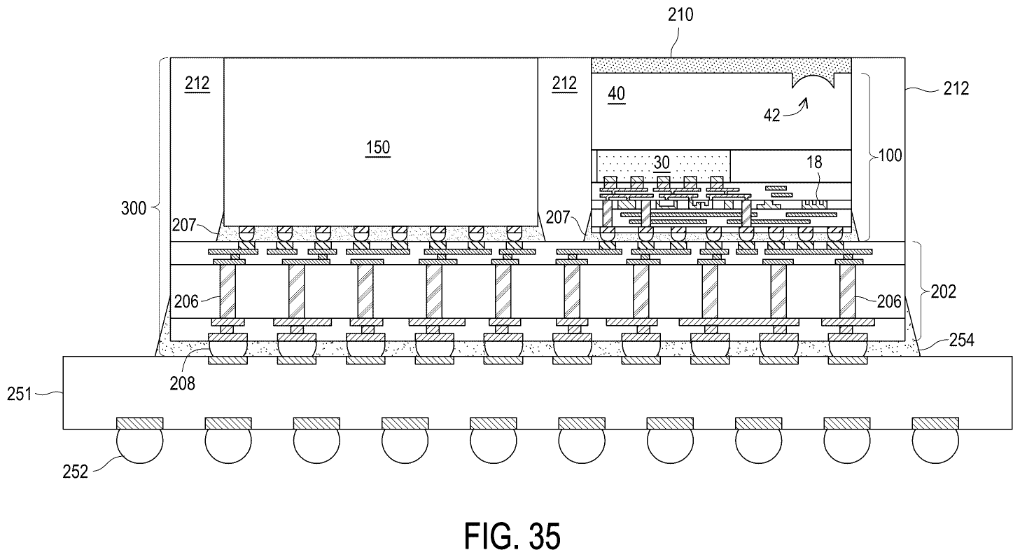

FIGS. 35 through 38 illustrate the formation of a package 350 comprising a package component 300, in accordance with some embodiments. The package 350 is similar to the package 250 described previously for FIGS. 16-20, except the top side of the optical engine 100 is covered by the protective coating 210. The package 250 of FIGS. 16-20 and the package 350 of FIGS. 35-38 may be formed using similar materials, techniques, or process steps. Accordingly, some details may not be repeated in the following discussion.

In FIG. 35, the package component 300 is attached to a package substrate 251, in accordance with some embodiments. The package substrate 251 may be similar to the package substrate 251 described previously for FIG. 16, and the package component 300 may be attached in a similar manner.

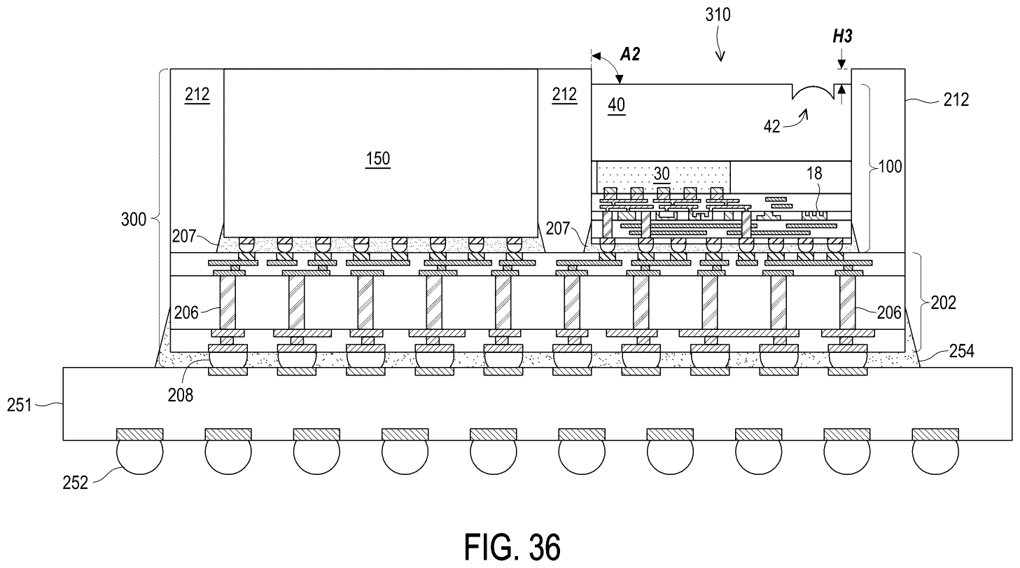

In FIG. 36, an etching process is performed to remove the protective coating 210 and expose the optical engine 100 and its lens 42, in accordance with some embodiments. Removing the protective coating 210 forms an opening 310 in the encapsulant that exposes the optical engine 100. Top surfaces of the optical engine 100 are thus recessed from top surfaces of the encapsulant 212. The etching process may be similar to the etching process described in FIG. 17. For example, the etching process may selectively etch the protective coating 210 without significantly etching other exposed materials of the package component 300 or package substrate 251.

The opening 310 may have a width that is approximately the same as a width of the optical engine 100. The opening 310 may have a height H3 (e.g., a “step height”) that is about the same as the thickness T3 of the protective coating 210 (see FIG. 34). The height H3 may be controlled by controlling the planarization process to remove upper portions of the protective coating 210, described above for FIG. 34. As shown in FIG. 36, the opening 310 may have substantially vertical sidewalls. For example, the sidewalls of the opening 310 may have an angle A2 that is in the range of about 85° to about 95°, though other angles are possible. In other embodiments, the sidewalls of the opening 310 may be angled, tapered, or curved.

In FIG. 37, a lid 270 is attached to the structure to form a package 350, in accordance with some embodiments. The lid 270 may be similar to the lid 270 described previously for FIG. 19. For example, the lid 270 may comprise a suitable material such as metal and may be attached to the package substrate 251 by an adhesive 271. In some embodiments, the lid 270 extends over the encapsulant 212 and/or the semiconductor die 150 of the package component 300. The lid 270 may fully cover the semiconductor die 150, in some cases.

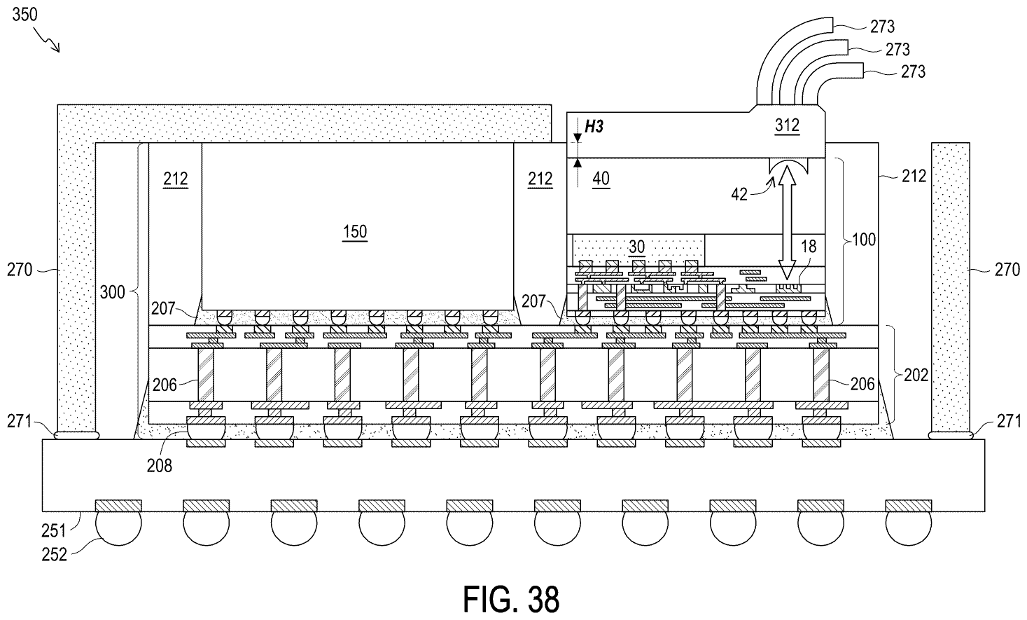

In FIG. 38, a fiber coupler 312 is attached to the package 350, in accordance with some embodiments. The fiber coupler 312 may be similar to the fiber coupler 272 described previously for FIG. 20, except that the fiber coupler 312 covers the top surface of the optical engine 100. The fiber coupler 312 may fully cover the top surface of the optical engine 100 as shown in FIG. 38, or may partially cover the top surface of the optical engine 100. The fiber coupler 312 facilitates the optical coupling of one or more optical fibers 273 with the package 350. For example, optical signals may be transmitted from one or more optical fibers 273 to the fiber coupler 312, and from the fiber coupler 312 to the lens 42. The optical signals (represented by the dashed arrow in FIG. 20) may then be transmitted from the lens 42 through dielectric layers of the optical engine 100 to a photonic component 18. Optical signals may also be transmitted from a photonic component 18 to the lens 42, from the lens 42 into the fiber coupler 272, and from the fiber coupler 272 into one or more optical fibers 273. The fiber coupler 312 may be attached to the package component 300 using an adhesive, an optical glue, an index matching gel, or the like. For example, in some cases, an adhesive, an optical glue, an index matching gel, or the like may be deposited on the lens 42 and/or on top surfaces of the support 40 prior to attachment of the fiber coupler 312.

In some embodiments, the height H3 of the opening 310 may be controlled to provide a height suitable for the fiber coupler 312. In some cases, the opening 310 may be formed having a specific height H3 that corresponds to a specific fiber coupler 312. Forming the opening 310 to have a particular height H3 may allow for improved attachment of the fiber coupler 312 and smaller package 350 size. In some embodiments, the fiber coupler 312 may extend below a top surface of the support 40. In some embodiments, the fiber coupler 312 and the opening 310 may have similar widths. Accordingly, the fiber coupler 312 and the optical engine 100 may have similar widths.

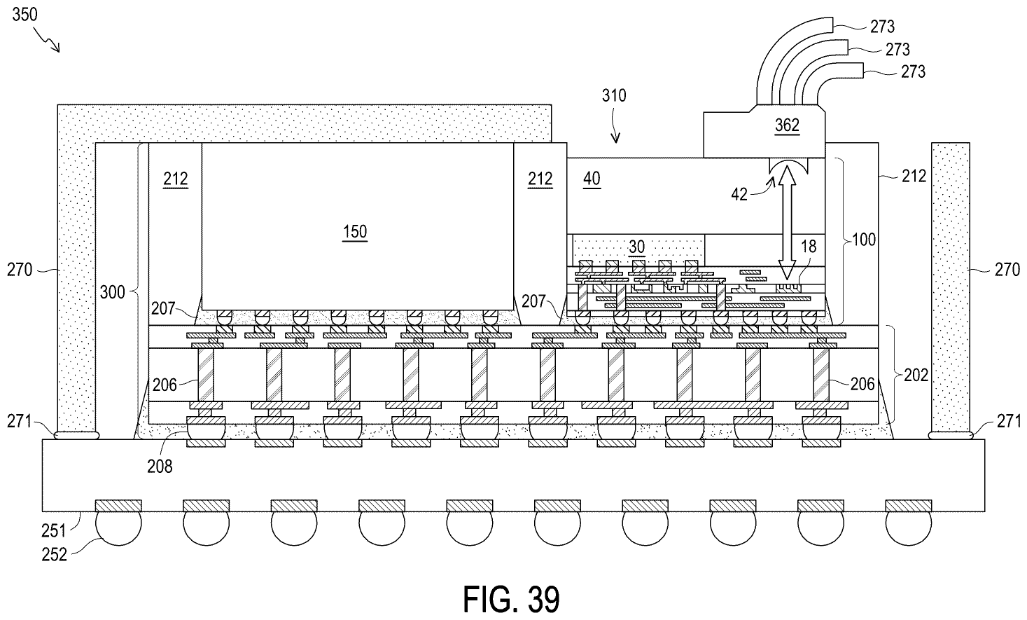

FIG. 39 illustrates a package 360 comprising a fiber coupler 362, in accordance with some embodiments. The package 360 is similar to the package 350 of FIG. 38, except the fiber coupler 362 does not fully cover the top of the optical engine 100. In other words, the fiber coupler 362 has a width that is smaller than a width of the opening 310. Accordingly, top surfaces of the optical engine 100 may be exposed and may be recessed from top surfaces of the encapsulant 212. In some embodiments, the fiber coupler 362 may cover a region above the lens 42, similar to the embodiment of FIG. 24. The fiber coupler 362 of FIG. 39 is an example, and other sizes, shapes, or configurations are possible.

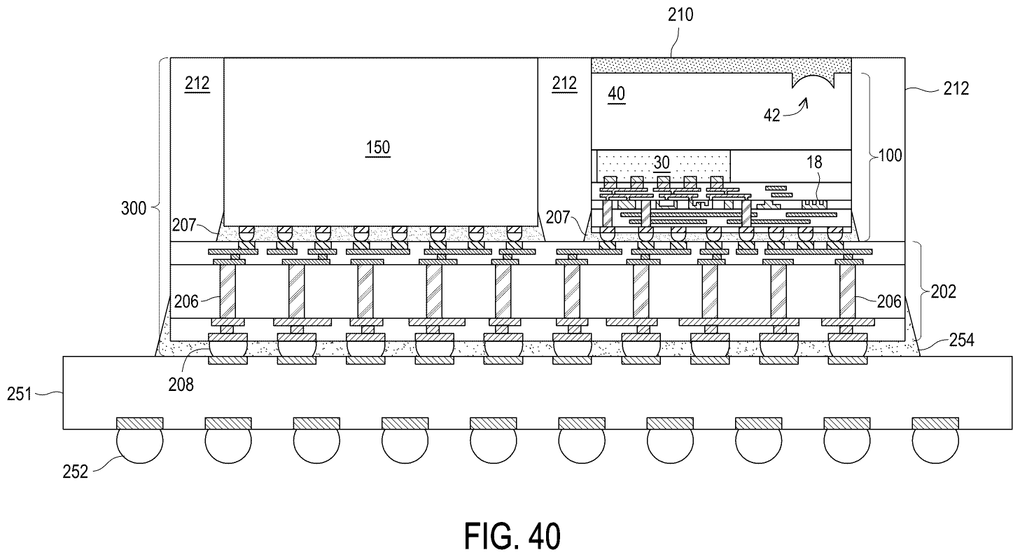

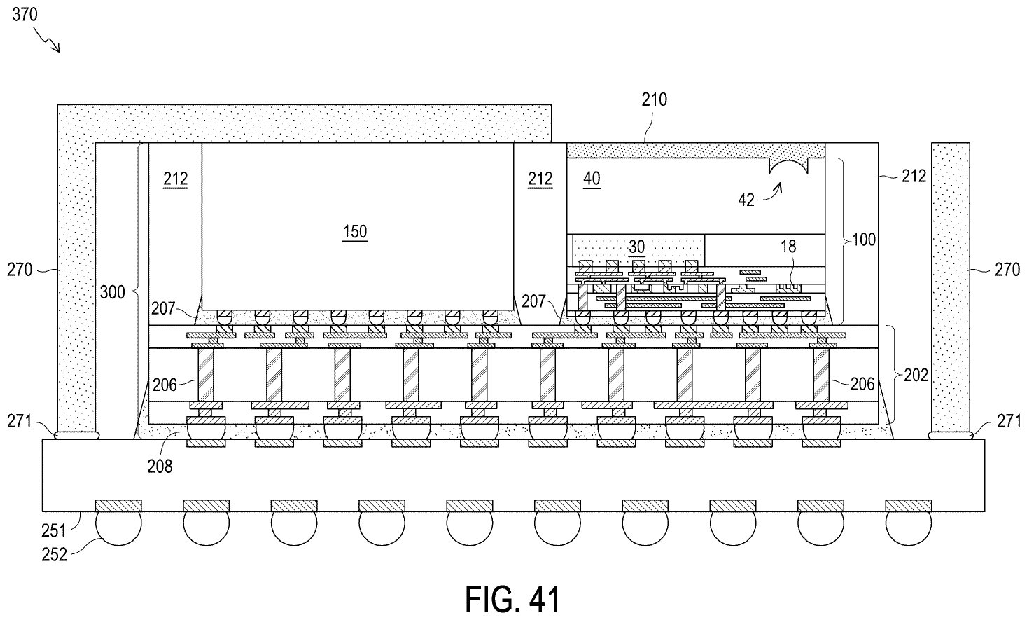

FIGS. 40 through 43 illustrate intermediate stages in the formation of a package 370 (see FIG. 41) comprising a package component 300, in accordance with some embodiments. The package component 300 is similar to the package component 300 described previously for FIG. 34. The package 370 is similar to the package 350 described for FIGS. 26-35, except that the protective coating 210 is removed after attachment of the lid 270. The package 370 may be formed using some materials, techniques, and/or process steps that are similar to those used to form the package 350. Accordingly, some details may not be repeated in the following discussion.

FIG. 40 shows a structure similar to that described previously for FIG. 35. For example, FIG. 40 illustrates a package component 300 attached to a package substrate 251, which may be similar to the package component 300 and package substrate 251 described for FIG. 35. The structure of FIG. 40 may be formed using materials, techniques, and/or process steps similar to those described previously for FIGS. 26-35.

In FIG. 41, a lid 270 is attached to the structure to form a package 370, in accordance with some embodiments. The lid 270 may be similar to the lid 270 described previously for FIG. 37. For example, the lid 270 may comprise a suitable material such as metal and may be attached to the package substrate 251 by an adhesive 271. In some embodiments, the lid 270 extends over the encapsulant 212 and/or the semiconductor die 150 of the package component 300. The lid 270 may fully cover the semiconductor die 150, in some cases. It should be noted that the protective coating 210 is not removed before attachment of the lid 270.

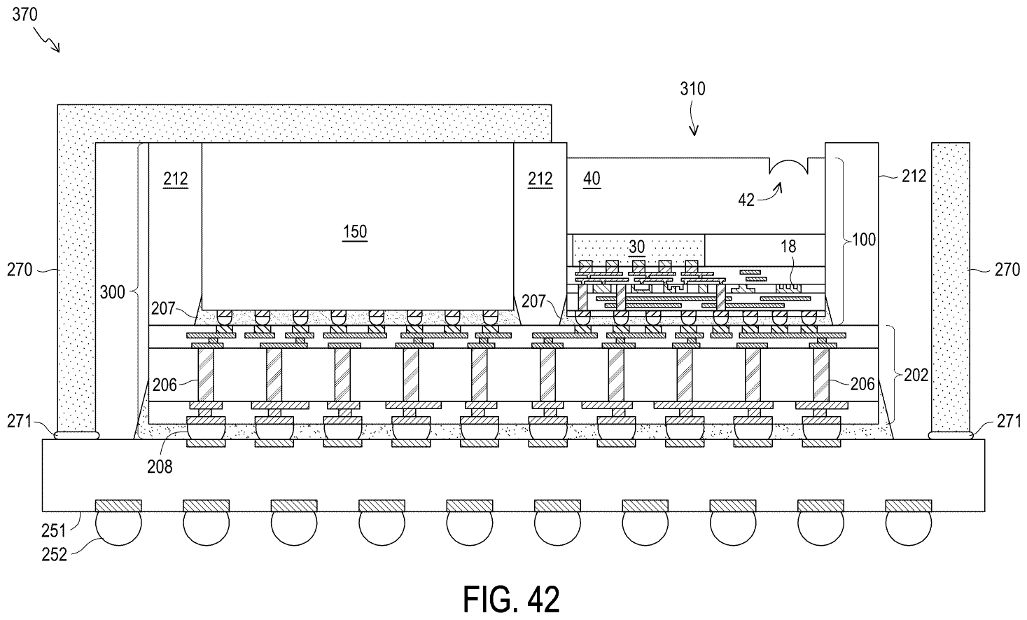

In FIG. 42, an etching process is performed to remove the protective coating 210 and expose the lens 42, in accordance with some embodiments. Removing the protective coating 210 forms an opening 310 in the encapsulant that exposes the top surface of the optical engine 100, similar to the step shown in FIG. 36. In some embodiments, the etching process may selectively etch the protective coating 210 without significantly etching other exposed materials of the package component 300 or package substrate 251. For example, the etching process may etch the material of the protective coating 210 at a greater rate than the material of the encapsulant 212 and/or the adhesive 271. In some embodiments, the etching selectivity of the protective coating 210 with respect to the adhesive 271 may be in the range of about 5:1 to about 100:1, though other selectivities are possible. For example, in embodiments in which the adhesive 271 comprises a siloxane material (e.g., dimethyl siloxane or the like), a silicone material, or the like, the etching process may be a wet etch comprising one or more suitable etchants such as propylene glycol monomethyl ether, propylene glycol monomethyl ether acetate, diethylene glycol monomethyl ether, 3-methoxy-3-methyl-1-butanol, tetramethylammonium hydroxide (TMAH), the like, or a combination thereof. Other etchants are possible, and the particular etchant(s) used, the particular combination of etchants used, and/or the particular ratio of etchants used may depend on the particular materials of the protective coating 210, the encapsulant 212, or the adhesive 271.

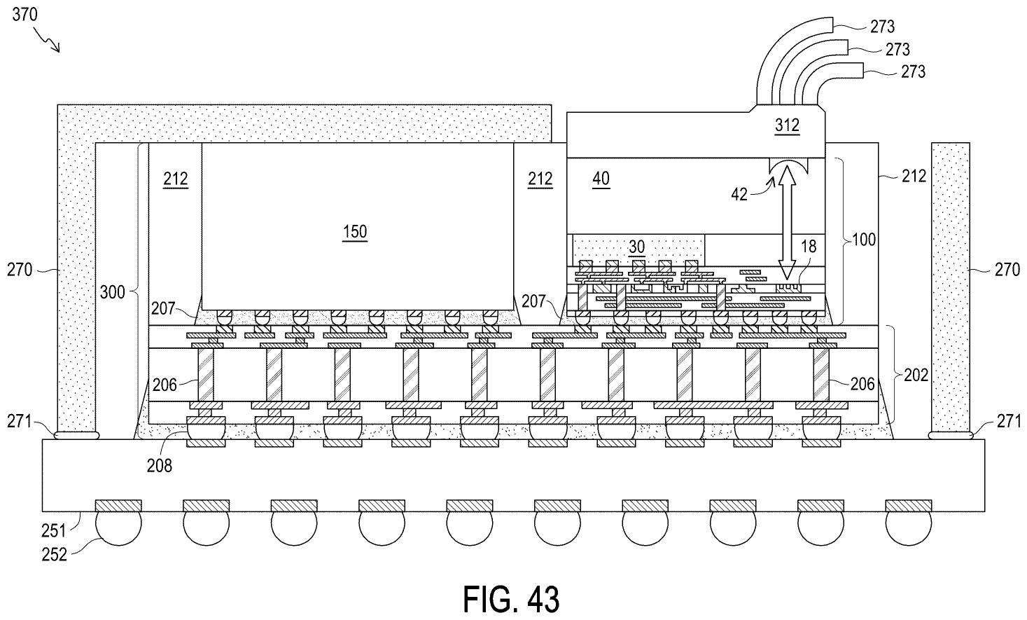

In FIG. 43, a fiber coupler 312 is attached to the package 370, in accordance with some embodiments. The fiber coupler 312 may be similar to the fiber coupler 312 described previously for FIG. 38. For example, the fiber coupler 312 covers the top surface of the optical engine 100. The fiber coupler 312 may fully cover the top surface of the optical engine 100, as shown in FIG. 43. This is an example, and other packages, package components, optical engines, or the like may have different configurations, arrangements, or manufacturing steps in other embodiments.

Embodiments of the present disclosure have some advantageous features. Forming a protective coating over the lens of an optical engine as described herein can reduce the risk of damage to the lens. For example, the protective coating can protect the lens during subsequent processing steps or packaging processes. The protective coating may be a temporary material that is removable at an appropriate later process step. The protective coating may be removed using an etch that is selective to the material of the protective coating to minimize damage or undesirable etching of the package. Techniques described herein allow for the lens of an optical engine to be protected as the optical engine is encapsulated. Additionally, techniques described herein allow for an opening in the encapsulant over the lens to be configured to receive a particular fiber coupling (e.g., a FAU or the like). Some techniques described herein allow for the top surface of the optical engine to be recessed from the encapsulant, which can be controlled to appropriately correspond to a particular fiber coupling. In this manner, techniques described herein can improve package reliability, reduce package size, improve optical coupling, and improve device performance.

In an embodiment, a method includes depositing a protective layer on a top surface of a photonic engine, wherein the top surface of the photonic engine includes a lens structure, wherein the protective layer covers the lens structure; depositing an encapsulant over the top surface of the photonic engine and the protective layer; and after depositing the encapsulant, removing the protective layer to expose the lens structure. In an embodiment, the method includes performing a planarization process on the encapsulant to expose the protective layer. In an embodiment, the protective layer includes acrylic resin or novolak resin. In an embodiment, the method includes performing a singulation process through the protective layer. In an embodiment, the method includes attaching a fiber array unit to the photonic engine, wherein the fiber array unit is optically coupled to the lens structure. In an embodiment, the encapsulant extends on the top surface of the photonic engine after removing the protective layer. In an embodiment, after removing the protective layer, the top surface of the photonic engine is free of the encapsulant.

In an embodiment, a method includes forming a package component including attaching an optical engine to an interposer; depositing a polymer on a top surface of the optical engine; and encapsulating the optical engine with an encapsulant; attaching the package component to a package substrate; removing the polymer to expose the optical engine; and attaching a fiber coupling to the package component over the optical engine. In an embodiment, the polymer is deposited before attaching the optical engine to the interposer. In an embodiment, the polymer extends over a lens in the top surface of the optical engine. In an embodiment, the polymer completely covers the top surface of the optical engine. In an embodiment, removing the polymer includes performing a selective etching process that etches the polymer at a greater rate than the encapsulant. In an embodiment, the fiber coupling is optically coupled to a photonic component of the optical engine. In an embodiment, the method includes attaching a lid to the package substrate, wherein the lid partially covers a top surface of the package component. In an embodiment, the lid is attached before removing the polymer.

In an embodiment, a package includes a package component including an optical engine bonded to an interposer, wherein the optical engine includes a lens; and an encapsulant over the optical engine and the interposer, wherein the encapsulant includes an opening over the lens; and a fiber coupling on the encapsulant, wherein the fiber coupling is optically coupled to the lens through the opening. In an embodiment, sidewalls of the opening have an angle in the range of 60° to 85°. In an embodiment, a thickness of the encapsulant over the optical engine is in the range of 10 μm to 100 μm. In an embodiment, the package component includes a semiconductor die. In an embodiment, the package includes a heat sink over surfaces of the encapsulant, wherein the heat sink includes an opening over the lens.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
depositing a protective layer on a top surface of a photonic engine, wherein the top surface of the photonic engine comprises a lens structure, wherein the protective layer covers the lens structure;
depositing an encapsulant over the top surface of the photonic engine and the protective layer; and
after depositing the encapsulant, removing the protective layer to expose the lens structure.

2. The method of claim 1 further comprising performing a planarization process on the encapsulant to expose the protective layer.

3. The method of claim 1, wherein the protective layer comprises acrylic resin or novolak resin.

4. The method of claim 1 further comprising performing a singulation process through the protective layer.

5. The method of claim 1 further comprising attaching a fiber array unit to the photonic engine, wherein the fiber array unit is optically coupled to the lens structure.

6. The method of claim 1, wherein the encapsulant extends on the top surface of the photonic engine after removing the protective layer.

7. The method of claim 1, wherein after removing the protective layer, the top surface of the photonic engine is free of the encapsulant.

8. A method comprising:
forming a package component comprising:
attaching an optical engine to an interposer;
depositing a polymer on a top surface of the optical engine; and
encapsulating the optical engine with an encapsulant;
attaching the package component to a package substrate;
removing the polymer to expose the optical engine; and
attaching a fiber coupling to the package component over the optical engine.

9. The method of claim 8, wherein the polymer is deposited before attaching the optical engine to the interposer.

10. The method of claim 8, wherein the polymer extends over a lens in the top surface of the optical engine.

11. The method of claim 8, wherein the polymer completely covers the top surface of the optical engine.

12. The method of claim 8, wherein removing the polymer comprises performing a selective etching process that etches the polymer at a greater rate than the encapsulant.

13. The method of claim 8, wherein the fiber coupling is optically coupled to a photonic component of the optical engine.

14. The method of claim 8 further comprising attaching a lid to the package substrate, wherein the lid partially covers a top surface of the package component.

15. The method of claim 14, wherein the lid is attached before removing the polymer.

16. A package comprising:
a package component comprising:
an optical engine bonded to an interposer, wherein the optical engine comprises a lens; and
an encapsulant over the optical engine and the interposer, wherein the encapsulant comprises an opening over the lens; and
a fiber coupling on the encapsulant, wherein the fiber coupling is optically coupled to the lens through the opening.

17. The package of claim 16, wherein sidewalls of the opening have an angle in the range of 60° to 85°.

18. The package of claim 16, wherein a thickness of the encapsulant over the optical engine is in the range of 10 μm to 100 μm.

19. The package of claim 16, wherein the package component further comprises a semiconductor die.

20. The package of claim 19 further comprising a heat sink over surfaces of the encapsulant, wherein the heat sink comprises an opening over the lens.
